(19) United States
(12) Patent Application Publication
(10) Pub. No.: US 2026/0026369 A1
(43) Pub. Date: Jan. 22, 2026

(54) SEMICONDUCTOR PACKAGE

(71) Applicant: SAMSUNG ELECTRONICS CO., LTD., Suwon-si (KR)

(72) Inventors: Hyeonjeong HWANG, Suwon-si (KR); Hyunsoo CHUNG, Suwon-si (KR)

(73) Assignee: SAMSUNG ELECTRONICS CO., LTD., Suwon-si (KR)

(21) Appl. No.: 19/010,971

(22) Filed: Jan. 6, 2025

(30) Foreign Application Priority Data
Jul. 17, 2024 (KR) 10-2024-0094551

(51) Int. Cl. H01L 23/00; H01L 25/07

(52) U.S. Cl. CPC H01L 24/24; H01L 24/19; H01L 24/20; H01L 24/32; H01L 24/73; H01L 25/074; H01L 2224/19; H01L 2224/215; H01L 2224/24105; H01L 2224/24146; H01L 2224/244; H01L 2224/32145; H01L 2224/73217; H01L 2225/06562

(57) ABSTRACT

A semiconductor package may include: a package substrate; a base semiconductor chip above the package substrate, the base semiconductor chip including a base pad in contact with the package substrate; at least one stacked semiconductor chip above the base semiconductor chip, the at least one stacked semiconductor chip including a chip pad connected to the package substrate; and an organic layer between the package substrate and the at least one stacked semiconductor chip in a first direction perpendicular to a surface of the package substrate; at least one connection structure in the organic layer, the at least one connection structure connecting the package substrate and the chip pad of the at least one stacked semiconductor chip, wherein the at least one connection structure includes a filling layer and a surface layer surrounding at least a portion of the filling layer.

### CROSS-REFERENCE TO RELATED APPLICATION

This application claims the benefit of Korean Patent Application No. 10-2024-0094551, filed on Jul. 17, 2024, in the Korean Intellectual Property Office, the disclosure of which is incorporated herein by reference in its entirety.

### BACKGROUND

### 1. Field

Example embodiments of the present disclosure relate to a semiconductor package.

### 2. Description of Related Art

Based on the rapidly developing electronics industry and user demands, electronic devices are becoming more downsized and multi-functional and have higher capacity. To implement these features, a semiconductor package including a plurality of semiconductor chips is demanded. In particular, various manners may be used to connect each of the plurality of semiconductor chips to a package substrate. For example, each semiconductor chip may be connected to the package substrate using wires.

Meanwhile, to connect each of the plurality of semiconductor chips to the package substrate, a manner of forming a post connected to the semiconductor chip and the package substrate and molding may be used. In this manner, after stacking two semiconductor chips, a photoresist (PR) is applied to form the post, but a bubble is generated due to a step of the stacked semiconductor chips, which may lead to a sharp reduction in yield. In addition, this manner stacks two semiconductor chips, forms the post, and then performs molding, but an additional molding is to be performed to additionally stack a semiconductor chip, which may cause a rise in costs and make it difficult to downsize products.

### SUMMARY

According to embodiments of the present disclosure, a semiconductor package is provided in which a sharp reduction in yield is decreased by alleviating a bubble occurrence and that has a structure that easily relieves a rise in costs and easily enables downsizing of products.

According to embodiments of the present disclosure, a semiconductor package may be provided and include: a package substrate; a base semiconductor chip above the package substrate, the base semiconductor chip including a base pad in contact with the package substrate; at least one stacked semiconductor chip above the base semiconductor chip, the at least one stacked semiconductor chip including a chip pad connected to the package substrate; and an organic layer between the package substrate and the at least one stacked semiconductor chip in a first direction perpendicular to a surface of the package substrate; at least one connection structure in the organic layer, the at least one connection structure connecting the package substrate and the chip pad of the at least one stacked semiconductor chip, wherein the at least one connection structure includes a filling layer and a surface layer surrounding at least a portion of the filling layer.

According to embodiments of the present disclosure, a method of fabricating a semiconductor package may be provided and include: a package substrate; a base semiconductor chip above the package substrate and including a base pad in contact with the package substrate; a plurality of stacked semiconductor chips including: a first stacked semiconductor chip that is above the base semiconductor chip and includes a first chip pad connected to the package substrate; and a second stacked semiconductor chip that is above the first stacked semiconductor chip and including a second chip pad connected to the package substrate; an organic layer that is between the package substrate and the plurality of stacked semiconductor chips in a first direction perpendicular to a surface of the package substrate; a first connection structure extending in the first direction in a first portion of the organic layer, the first connection structure connecting the package substrate and the first chip pad; a second connection structure extending in the first direction in a second portion of the organic layer, the second connection structure connecting the package substrate and the second chip pad; and a molding film on the base semiconductor chip and the plurality of stacked semiconductor chips, wherein the first portion of the organic layer is between the first stacked semiconductor chip and the package substrate, and the second portion of the organic layer is between the second stacked semiconductor chip and the package substrate, and wherein, in the first direction perpendicular to the surface of the package substrate, a thickness of the first portion and a thickness of the second portion are different from each other.

According to embodiments of the present disclosure, a semiconductor package may be provided and include: a package substrate; a base semiconductor chip above the package substrate and including a base pad in contact with the package substrate; a plurality of stacked semiconductor chips including: a first stacked semiconductor chip that is above the base semiconductor chip and includes a first chip pad that is configured to be electrically connected to the package substrate; and a second stacked semiconductor chip that is above the first stacked semiconductor chip and including a second chip pad that is configured to be electrically connected to the package substrate; an organic layer that is between the package substrate and the plurality of stacked semiconductor chips in a first direction perpendicular to a surface of the package substrate; a first connection structure extending in the first direction in a first portion of the organic layer, the first connection structure configured to electrically connect the package substrate to the first chip pad; a second connection structure extending in the first direction in a second portion of the organic layer, the second connection structure configured to electrically connect the package substrate to the second chip pad; a molding film on the base semiconductor chip and the plurality of stacked semiconductor chips, wherein the first portion of the organic layer is between the first stacked semiconductor chip and the package substrate, and the second portion of the organic layer is between the second stacked semiconductor chip and the package substrate, and wherein, in the first direction perpendicular to the surface of the package substrate, a thickness of the first portion and a thickness of the second portion are different from each other.

Additional aspects of example embodiments of the present disclosure will be set forth in part in the description which follows and, in part, will be apparent from the description, or may be learned by practice of the present disclosure.

According to example embodiments of the present disclosure, it is possible to provide a semiconductor package in which a sharp reduction in yield is decreased by alleviating a bubble occurrence and that has a structure that easily relieves a rise in costs and easily enables downsizing of products.

Embodiments of the present disclosure are not limited to the aspects and effects described above, and other unstated aspects and effects may be may be clearly understood by those skilled in the art from the following description.

### BRIEF DESCRIPTION OF DRAWINGS

The drawings of the present disclosure are provided to illustrate example embodiments, and a ratio of width, length, or height (or thickness) of each element is to describe the example embodiments in detail and the ratio may be different from the actual ratio. Further, in a coordinate system shown in the drawings, each axis may be perpendicular to one another, and a direction pointed by an arrow may be positive direction and a directly opposite direction (a direction turned by 180 degrees) to the direction pointed by the arrow may be negative direction.

These and/or other aspects, features, and advantages of embodiments of the present disclosures will become apparent and more readily appreciated from the following description of example embodiments, taken in conjunction with the accompanying drawings of which:

FIG. 1 is a cross-sectional view showing a semiconductor package according to a first example embodiment of the present disclosure;

FIG. 2 is a cross-sectional view showing a semiconductor package according to a second example embodiment of the present disclosure;

FIG. 3 is a cross-sectional view showing a process of applying an organic layer precursor on a base layer in a method of fabricating a semiconductor package according to an example embodiment of the present disclosure;

FIG. 4 is a cross-sectional view showing forming a step-structured organic layer with an organic layer precursor in a method of fabricating a semiconductor package according to an example embodiment of the present disclosure;

FIG. 5 is a cross-sectional view showing stacking a base semiconductor chip and a stacked semiconductor chip on a package substrate in a method of fabricating a semiconductor package according to an example embodiment of the present disclosure;

FIG. 6 is a cross-sectional view showing forming a molding film in a method of fabricating a semiconductor package according to an example embodiment of the present disclosure;

FIG. 7 is a cross-sectional view showing disposing a carrier layer above a molding film in a method of fabricating a semiconductor package according to an example embodiment of the present disclosure;

FIG. 8 is a cross-sectional view showing removing a portion of a base layer after a flip in a method of fabricating a semiconductor package according to an example embodiment of the present disclosure;

FIG. 9 is a cross-sectional view showing applying a photoresist in a method of fabricating a semiconductor package according to an example embodiment of the present disclosure;

FIG. 10 is a cross-sectional view showing forming a trench by etching a step-structured organic layer in a method of fabricating a semiconductor package according to the first example embodiment of the present disclosure;

FIG. 11 is a cross-sectional view showing removing a photoresist in a method of fabricating a semiconductor package according to the first example embodiment of the present disclosure;

FIG. 12 is a cross-sectional view showing forming a seed metal layer in a method of fabricating a semiconductor package according to the first example embodiment of the present disclosure;

FIG. 13 is a cross-sectional view showing forming a connection layer in a method of fabricating a semiconductor package according to the first example embodiment of the present disclosure;

FIG. 14 is a cross-sectional view showing removing the remainder excluding a seed metal layer and a connection layer disposed within a trench in a method of fabricating a semiconductor package according to the first example embodiment of the present disclosure;

FIG. 15 is a cross-sectional view showing removing a barrier metal layer through a polishing process in a method of fabricating a semiconductor package according to the first example embodiment of the present disclosure;

FIG. 16 is a cross-sectional view showing forming a redistribution layer that arranges wiring in a package substrate in a method of fabricating a semiconductor package according to the first example embodiment of the present disclosure;

FIG. 17 is a cross-sectional view showing disposing an external connection terminal in a method of fabricating a semiconductor package according to the first example embodiment of the present disclosure;

FIG. 18 is a cross-sectional view showing a state before a flip of a semiconductor package in a method of fabricating a semiconductor package according to the first example embodiment of the present disclosure;

FIG. 19 is a cross-sectional view showing forming a trench by etching a step-structured organic layer in a method of fabricating a semiconductor package according to the second example embodiment of the present disclosure;

FIG. 20 is a cross-sectional view showing removing a photoresist in a method of fabricating a semiconductor package according to the second example embodiment of the present disclosure;

FIG. 21 is a cross-sectional view showing forming a seed metal layer in a method of fabricating a semiconductor package according to the second example embodiment of the present disclosure;

FIG. 22 is a cross-sectional view showing forming a connection layer in a method of fabricating a semiconductor package according to the second example embodiment of the present disclosure;

FIG. 23 is a cross-sectional view showing removing a remainder excluding a seed metal layer and a connection layer disposed within a trench in a method of fabricating a semiconductor package according to the second example embodiment of the present disclosure;

FIG. 24 is a cross-sectional view showing removing a barrier metal layer through a polishing process in a method of fabricating a semiconductor package according to the second example embodiment of the present disclosure;

FIG. 25 is a cross-sectional view showing forming a redistribution layer that arranges wiring in a package substrate in a method of fabricating a semiconductor package according to the second example embodiment of the present disclosure;

FIG. 26 is a cross-sectional view showing disposing an external connection terminal in a method of fabricating a semiconductor package according to the second example embodiment of the present disclosure; and

FIG. 27 is a cross-sectional view showing a state before a flip of a semiconductor package in a method of fabricating a semiconductor package according to the second example embodiment of the present disclosure.

### DETAILED DESCRIPTION

Words and terminologies used in the specification and claims may not be construed as limited to common or dictionary meanings. In addition, the words and terminologies may be construed as meanings and conceptions coinciding with the technical spirit of the present disclosure under a principle that the inventor(s) may appropriately define the conception of the terminologies to explain the present disclosure. The embodiments described in the specification and illustrated in the drawings are non-limiting example embodiments. Therefore, various equivalents and modifications are included within the spirit and scope of the present disclosure.

Like reference numerals or letters in each drawing may refer to components or elements performing substantially like functions. For convenience of description and understanding, the same reference numeral or letter may be used for description in different example embodiments. In other words, although elements with the same reference numeral may be illustrated in the drawings, all of the drawings may not represent a single example embodiment.

When an element is referred to as being “directly on,” “contacting,” or “in contact with” another element herein, it may be understood that the element may be in direct contact with or directly connected to another element and there are no intervening elements present in between.

Further, when an element is referred to as being “above” or “on an upper surface of” another element herein, it may be understood that the element is present above based on a vertical direction or, for example, above based on a positive direction D1 in a drawing, and it may be understood that the element may be in direct contact with or directly connected to another element or an intervening element may be present in between. When an element is referred to as being “on” another element herein, it may also be similarly understood.

Further, when an element is referred to as being “below” or “on a bottom surface of” another element herein, it may be understood that the element is present below based on a vertical direction or, for example, below based on a negative direction D1 in a drawing, and it may be understood that the element may be in direct contact with or directly connected to another element or an intervening element may be present in between. When an element is referred to as being “under” another element herein, it may also be similarly understood.

Other similar expressions describing position relationships between elements may also be similarly construed as above.

In the descriptions below, a singular expression includes a plural expression unless apparently otherwise defined by context. In the present disclosure, it may be understood that terms such as “comprise” or “include” are intended to indicate the presence of a feature, a number, a step, an operation, an element, a component, or a combination thereof which are described in the specification and not intended to exclude the possibility of the presence or addition of one or more other features, numbers, steps, operations, elements, components, or combinations thereof.

In addition, expressions such as “upper side,” “upper surface,” “lower side,” “bottom surface,” “side surface,” “front surface,” and “rear surface” hereinafter are represented based on a direction illustrated in a drawing and may be represented otherwise when the direction of a corresponding object changes.

Further, terms including ordinal numbers such as “first” and “second” may be used to differentiate between elements in the specification and claims. These ordinal numbers may be used to differentiate identical or similar elements from each other, and the use of the ordinal numbers may not limit the meanings of terms. As an example, an element combined with an ordinal number is not to be construed such that order or arrangement thereof is limited by the ordinal number. In some cases, each ordinal number may also be used by replacing each other.

In addition, hereinafter, “US” indicated in reference letters refers to an upper surface present above based on the positive direction D1 in the drawings.

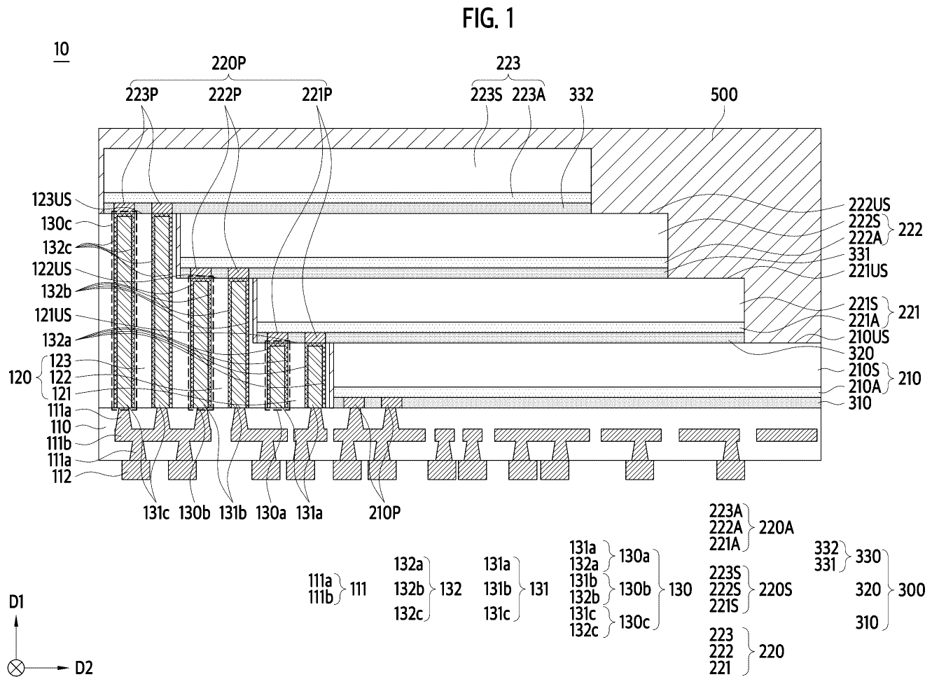

FIG. 1 is a cross-sectional view showing a semiconductor package 10 according to a first example embodiment of the present disclosure.

The semiconductor package 10 according to an example embodiment of the present disclosure may include a package substrate 110. In an example, the package substrate 110 may be a wiring structure for a package. For example, the package substrate 110 may be a printed circuit board (PCB), a ceramic wiring board, or an interposer. Alternatively, the package substrate 110 may also be a wiring structure for a wafer-level package (WLP) fabricated at a wafer level. In an example, the package substrate 110 may be a semiconductor chip including a semiconductor device. In an example, the package substrate 110 may function as a support substrate of the semiconductor package 10.

In an example, the package substrate 110 may be, but is not limited to, a glass substrate, a ceramic substrate, or a plastic substrate. For example, the package substrate 110 may include a resin impregnated along with an inorganic filler into a core material such as glass fiber (or glass cloth or glass fabric) such as, for example, Prepreg, Ajinomoto Build-up Film (ABF), FR-4, or bismaleimide triazine (BT).

In an example, the package substrate 110 may include or consist of at least one material selected from among phenolic resin, epoxy resin, and polyimide. The package substrate 110 may include at least one material selected from among tetrafunctional epoxy, polyphenylene ether, epoxy/polyphenylene oxide, bismaleimide triazine (BT), thermount, cyanate ester, and liquid crystal polymer.

In an example, the package substrate 110 may include a photoimageable dielectric. For example, the package substrate 110 may include a photosensitive polymer. The photosensitive polymer may be formed with, for example, at least one from among photosensitive polyimide, polybenzoxazole, phenolic polymer, and benzocyclobutene-based polymer. In another example, the package substrate 110 may be formed with a silicon oxide layer, a silicon nitride layer, or a silicon oxynitride layer.

According to some example embodiments of the present disclosures, the package substrate 110 may include, but is not limited to, a single layer or multiple layers of an insulating layer on at least one surface thereof.

In an example, the package substrate 110 may include a wiring structure 111 so that a base semiconductor chip 210 and at least one stacked semiconductor chip 220 to be described below may be electrically connected to the package substrate 110. The wiring structure 111 may include a wiring pattern 111a and a connection pattern 111b, and a plurality of the wiring patterns 111a may be electrically connected to each other through the connection pattern 111b. For example, the wiring pattern 111a may be disposed to be parallel to a first direction D1 perpendicular to a surface of the package substrate 110 and may be plural in number, and at least some thereof may be exposed in the (positive) first direction D1, adjacent to the base semiconductor chip 210, and at least some others thereof may be exposed in the (negative) first direction D1, adjacent to an external connection terminal 112 to be described below. The connection pattern 111b may electrically connect between the plurality of wiring patterns 111a. The wiring pattern 111a and the connection pattern 111b may each independently include a metal material, and the metal material may include one or more from among, for example, tungsten (W), aluminum (Al), copper (Cu), titanium (Ti), nickel (Ni), titanium nitride (TiN), tantalum (Ta), tantalum nitride (TaN), gold (Au), and silver (Ag).

In an example, the wiring structure 111 may be exposed from a surface of the package substrate 110 at a position corresponding to a base pad 210P of the base semiconductor chip 210 and a chip pad 220P of the at least one stacked semiconductor chip 220 to be described below. In the wiring structure 111, the number, gap, arrangement, and form of the wiring pattern 111a and the connection pattern 111b are not limited to the drawings and may be variously changed.

The semiconductor package 10 according to an example embodiment of the present disclosure may include the external connection terminal 112 electrically connected to the package substrate 110. The external connection terminal 112 may be electrically connected to the wiring structure 111. The external connection terminal 112 may include a solder ball or a solder bump. The external connection terminal 112 may include one or more from among, for example, tin (Sn), indium (In), bismuth (Bi), antimony (Sb), copper (Cu), silver (Ag), zinc (Zn), and lead (Pb). The number, gap, arrangement, and form of the external connection terminal 112 are not limited to the drawings and may be variously changed.

In an example, the external connection terminal 112 may electrically connect the wiring structure 111 to an external apparatus. Accordingly, the external connection terminal 112 may provide electrical signals to the wiring structure 111 or provide the external apparatus with electrical signals (e.g., a power signal, a ground signal, or an input/output signal) provided from the wiring structure 111.

The semiconductor package 10 according to an example embodiment of the present disclosure may include the base semiconductor chip 210 that is disposed above the package substrate 110 and includes the base pad 210P in contact with the package substrate 110. The semiconductor package 10 according to an example embodiment of the present disclosure may include the at least one stacked semiconductor chip 220 that is disposed above the base semiconductor chip 210 and includes the chip pad 220P electrically connected to the package substrate 110.

In an example, the base semiconductor chip 210 may include a base semiconductor substrate 210S and a base semiconductor active layer 210A disposed on one surface of the base semiconductor substrate 210S. In an example, one or more (e.g., some or all of) the at least one stacked semiconductor chip 220 may include a stacked semiconductor substrate 220S and a stacked semiconductor active layer 220A disposed on one surface of the stacked semiconductor substrate 220S.

In an example, the base semiconductor substrate 210S and the stacked semiconductor substrate 220S may each independently include, for example, silicon (Si). In addition, the base semiconductor substrate 210S and the stacked semiconductor substrate 220S may each independently include a compound semiconductor including one or more from among indium (In), gallium (Ga), zinc (Zn), silicon (Si), tin (Sn), zirconium (Zr), hafnium (Hf), aluminum (Al), and ytterbium (Yb). Alternatively, the base semiconductor substrate 210S and the stacked semiconductor substrate 220S may each independently have a silicon on insulator (SOI) structure in some cases. Alternatively, in some cases, the base semiconductor substrate 210S and the stacked semiconductor substrate 220S may each independently have a conductive region including a well doped with impurities or a structure doped with impurities. Alternatively, the base semiconductor substrate 210S and the stacked semiconductor substrate 220S may each independently have an element isolation structure such as shallow trench isolation (STI) in some cases.

In an example, the base semiconductor active layer 210A may include a surface on which the base pad 210P is disposed in the base semiconductor chip 210, and the stacked semiconductor active layer 220A may refer to a surface on which the chip pad 220P is disposed in the at least one stacked semiconductor chip 220.

In an example, the base pad 210P may have a structure protruding from the base semiconductor active layer 210A and, in another example, may have a structure that does not protrude. In addition, the chip pad 220P may have a structure protruding from the stacked semiconductor active layer 220A and, in another example, may have a structure of not protruding. In the drawings, the base pad 210P and the chip pad 220P protrude from each of the base semiconductor active layer 210A and the stacked semiconductor active layer 220A, but are not limited thereto.

In an example, the base pad 210P and the chip pad 220P may each independently have a conductive material. The conductive material may include one or more from among, for example, tungsten (W), aluminum (Al), copper (Cu), titanium (Ti), nickel (Ni), titanium nitride (TiN), tantalum (Ta), tantalum nitride (TaN), gold (Au), and silver (Ag).

In an example, when viewed in the first direction D1 perpendicular to the surface of the package substrate 110, the base pad 210P and the chip pad 220P may not overlap. In other words, the stacked semiconductor chip 220 may be disposed above the base semiconductor chip 210 so that the chip pad 220P and the base pad 210P do not overlap with each other in the first direction D1.

In an example, the at least one stacked semiconductor chip 220 may be disposed above the base semiconductor chip 210, on the base semiconductor chip 210, and shifted by a predetermined distance in a second direction D2 parallel to the surface of the package substrate 110. For example, the at least one stacked semiconductor chip 220 may be disposed to be offset from the base semiconductor chip 210 by a predetermined distance in the second direction D2. Accordingly, the chip pad 220P and the base pad 210P may not overlap with each other in the first direction D1.

In an example, the at least one stacked semiconductor chip 220 as a plurality of stacked semiconductor chips. The number of the plurality of stacked semiconductor chips 220 is not particularly limited. For example, the plurality of stacked semiconductor chips 220 may include a first stacked semiconductor chip 221, a second stacked semiconductor chip 222, and a third stacked semiconductor chip 223. The first stacked semiconductor chip 221 may include a first chip pad 221P, the second stacked semiconductor chip 222 may include a second chip pad 222P, and the third stacked semiconductor chip 223 may include a third chip pad 223P, which may each be one of the chip pads 220P. In the drawings, it is illustrated that three semiconductor chips (i.e., the first stacked semiconductor chip 221, the second stacked semiconductor chip 222, and the third stacked semiconductor chip 223) are stacked, but example embodiments are not limited thereto.

In an example, when viewed in the first direction D1 perpendicular to the surface of the package substrate 110, each chip pad 220P of the plurality of stacked semiconductor chips 220 may not overlap with each other. For example, the first stacked semiconductor chip 221 may be disposed above the base semiconductor chip 210, and the first chip pad 221P and the base pad 210P may not overlap with each other in the first direction D1. In addition, the second stacked semiconductor chip 222 may be disposed above the first stacked semiconductor chip 221, and the second chip pad 222P and the first chip pad 221P may not overlap with each other in the first direction D1. Meanwhile, in an example, the second chip pad 222P and the base pad 210P may also not overlap with each other in the first direction D1. In addition, the third stacked semiconductor chip 223 may be disposed above the second stacked semiconductor chip 222, and the third chip pad 223P and the second chip pad 222P may not overlap with each other in the first direction D1. Meanwhile, in an example, the third chip pad 223P and the first chip pad 221P and the third chip pad 223P and the base pad 210P may also not overlap with each other in the first direction D1.

In an example, the plurality of stacked semiconductor chips 220 may be stacked in a shifted manner by a predetermined distance in the second direction D2 parallel to the surface of the package substrate 110 in sequence. For example, the third stacked semiconductor chip 223 may be disposed above the second stacked semiconductor chip 222 and shifted by a predetermined distance in the second direction D2 parallel to the surface of the package substrate 110 from the second stacked semiconductor chip 222. In addition, the second stacked semiconductor chip 222 may be disposed above the first stacked semiconductor chip 221 and shifted by a predetermined distance in the second direction D2 parallel to the surface of the package substrate 110 from the first stacked semiconductor chip 221. In addition, the first stacked semiconductor chip 221 may be disposed above the base semiconductor chip 210 and shifted by a predetermined distance in the second direction D2 parallel to the surface of the package substrate 110 from the base semiconductor chip 210. Accordingly, when viewed from the first direction D1, each of the first chip pad 221P, the second chip pad 222P, and the third chip pad 223P may not overlap with each other, and each of the first chip pad 221P, the second chip pad 222P, the third chip pad 223P, and the base pad 210P may not overlap each other.

The semiconductor package 10 according to an example embodiment of the present disclosure may include at least one bonding layer 300 for bonding elements. In an example, a base bonding layer 310 may be disposed between the package substrate 110 and the base semiconductor chip 210 in the semiconductor package 10. Further, in an example, a connection bonding layer 320 may be disposed between the base semiconductor chip 210 and the at least one stacked semiconductor chip 220 (e.g., the first stacked semiconductor chip 221) in the semiconductor package 10. Further, in an example, at least one chip bonding layer 330 may be disposed between neighboring stacked semiconductor chips from among the plurality of stacked semiconductor chips 220 in the semiconductor package 10. In other words, the at least one bonding layer 300 may include at least one from among the base bonding layer 310, the connection bonding layer 320, and the chip bonding layer 330.

For example, the base bonding layer 310 may be disposed between the package substrate 110 and the base semiconductor chip 210. In addition, the connection bonding layer 320 may be disposed between the base semiconductor chip 210 and the first stacked semiconductor chip 221. Further, a first chip bonding layer 331 may be disposed between the second stacked semiconductor chip 222 and the first stacked semiconductor chip 221, and a second chip bonding layer 332 may be disposed between the third stacked semiconductor chip 223 and the second stacked semiconductor chip 222.

In an example, at least one from among the base bonding layer 310, the connection bonding layer 320, and the chip bonding layer 330 may independently include an adhesive resin and a conductive particle dispersed in the adhesive resin. The adhesive resin is not particularly limited and may include one or more from among, for example, acrylic resin, vinyl acetate resin, ethylene-vinyl acetate copolymer, ethylene-acrylic acid ester copolymer, polyamide, polyethylene, polysulfone, epoxy resin, polyimide, polyamide acid, silicone phenol rubber polymer, fluorine rubber polymer, and fluorine resin. The conductive particle is not particularly limited and may include, for example, one or more from among carbon fiber and metal (e.g., nickel, gold, or the like). At least one from among the base bonding layer 310, the connection bonding layer 320, and the chip bonding layer 330 may be configured to provide electrical connection between bonding targets while exerting adhesive force through the conductive particle dispersed in the adhesive resin. For example, at least one from among the base bonding layer 310, the connection bonding layer 320, and the chip bonding layer 330 may be a conductive film.

In an example, the base pad 210P may be embedded in the base bonding layer 310. Specifically, the base pad 210P with a structure protruding from the base semiconductor active layer 210A may be embedded in the base bonding layer 310. The base bonding layer 310 may electrically connect the base semiconductor chip 210 to the package substrate 110 through the conductive particle described above even though the base pad 210P is embedded therein, and satisfactory adhesive force may be obtained.

In an example, the chip pad 220P of the stacked semiconductor chip 220 may be embedded in the connection bonding layer 320. Specifically, the chip pad 220P of the stacked semiconductor chip 220 that is stacked directly above the base semiconductor chip 210 may be embedded in the connection bonding layer 320. For example, the first chip pad 221P of the first stacked semiconductor chip 221 that is stacked directly above the base semiconductor chip 210 may be embedded in the connection bonding layer 320. The connection bonding layer 320 may electrically connect between the stacked semiconductor chip 220 (e.g., the first stacked semiconductor chip 221) and the base semiconductor chip 210 through the conductive particle described above even though the chip pad 220P (e.g., the first chip pad 221P) is embedded therein, and satisfactory adhesive force may be obtained.

In an example, the chip pads 220P disposed between the plurality of stacked semiconductor chips 220 may be embedded in the chip bonding layers 330. For example, the second chip pad 222P between the first stacked semiconductor chip 221 and the second stacked semiconductor chip 222 may be embedded in the first chip bonding layer 331, and the third chip pad 223P between the second stacked semiconductor chip 222 and the third stacked semiconductor chip 223 may be embedded in the second chip bonding layer 332. The chip bonding layer 330 may electrically connect the stacked semiconductor chips 220 (e.g., the first stacked semiconductor chip 221 and the second stacked semiconductor chip 222 and/or the second stacked semiconductor chip 222 and the third stacked semiconductor chip 223) through the conductive particle described above even though the chip pads 220P (e.g.,, the second chip pad 222P and/or the third chip pad 223P) is embedded therein, and satisfactory adhesive force may be obtained.

In an example, the base semiconductor chip 210 and the stacked semiconductor chip 220 may each independently include a semiconductor device, and each semiconductor device may be electrically connected to the base semiconductor substrate 210S or the stacked semiconductor substrate 220S. The semiconductor device may be, for example, random-access memory (RAM) such as dynamic random-access memory (DRAM) and static random-access memory (SRAM), flash memory such as NOR flash and NAND flash, an application processor (AP) for a mobile device, a central processing unit (CPU) for a computer, a digital signal processor (DSP) that processes digital signals, light emitting diode, complementary metal oxide semiconductor (CMOS) that changes light into an image signal, an image sensor, a display driver integrated circuit (DDI), or other communication apparatuses. In addition, the base semiconductor chip 210 and the stacked semiconductor chip 220 may include an identical semiconductor device, except for having different positional relationships.

The semiconductor package 10 according to an example embodiment of the present disclosure may include an organic layer that is disposed between the package substrate 110 and the stacked semiconductor chip 220 in the first direction D1 perpendicular to the surface of the package substrate 110 and in which connection structures 130 electrically connecting the package substrate 110 and the chip pad 220P are embedded.

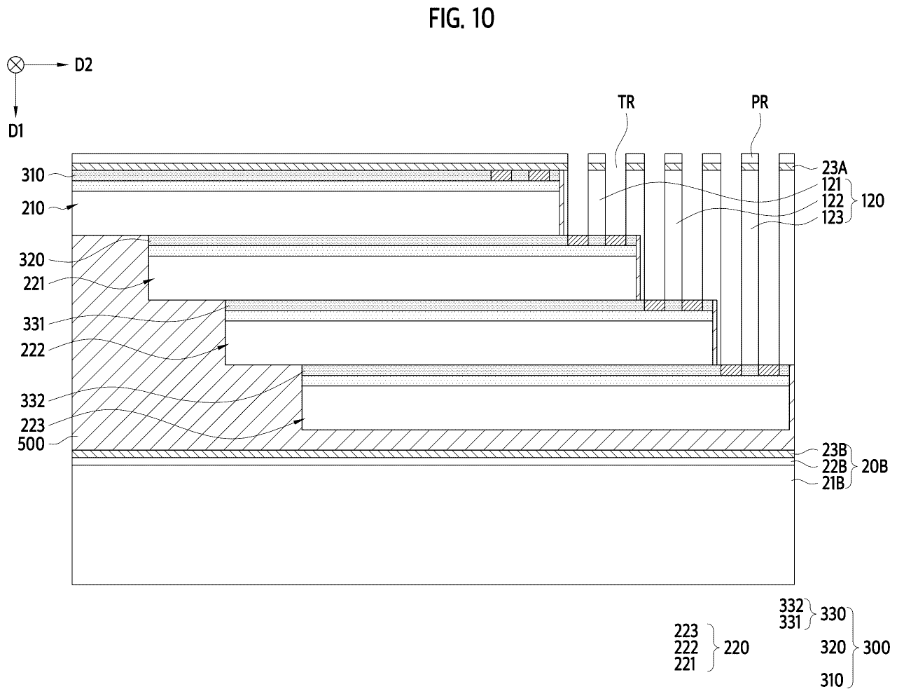

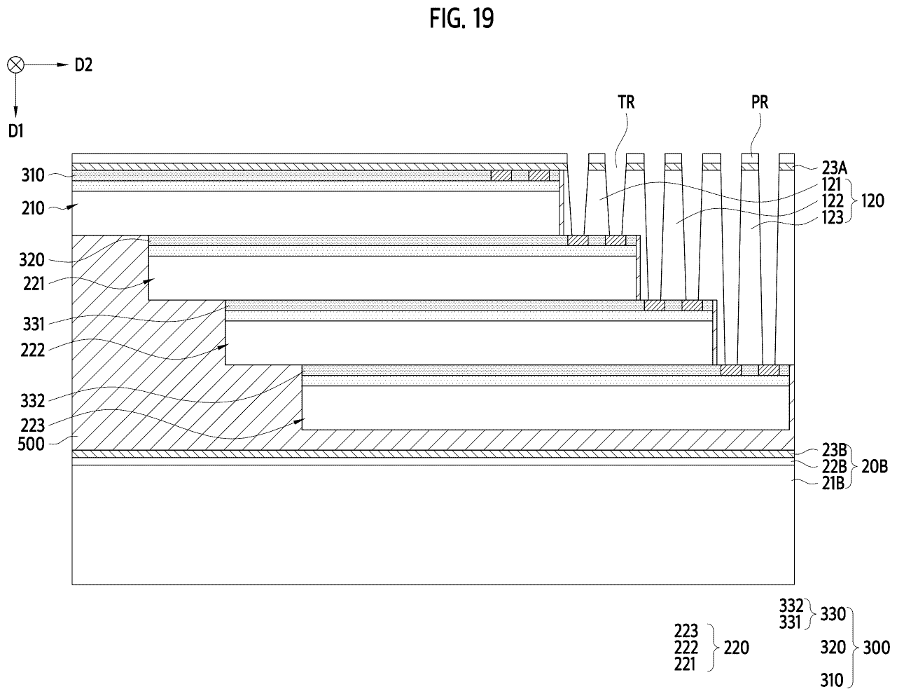

In an example, the connection structures 130 may each include a filling layer 131. The filling layer 131 may be a layer filling a trench (see trench TR of FIGS. 10 and 19) to be described below. The connection structures 130 may each include a surface layer 132 surrounding at least a portion of the filling layer 131.

In an example, the organic layer 120 may include, but is not limited to, a photoimageable dielectric (PID). In an example, the filling layer 131 may be formed with a conductive material and, for example, the filling layer 131 may include copper (Cu). In addition, the surface layer 132 may perform a role as a seed layer that may help form the filling layer 131 and may include one or more from among, for example, titanium (Ti), chrome (Cr), and copper alloy. The materials included in the filling layer 131 and the surface layer 132 may be different.

In an example, based on the second direction D2 parallel to the surface of the package substrate 110, one surface of the surface layer 132 may be in contact with the organic layer 120 and another surface may be in contact with the filling layer 131. Based on the second direction D2 parallel to the surface of the package substrate 110, the surface layer 132 alone may be disposed between the organic layer 120 and the filling layer 131.

In an example, based on the first direction D1 perpendicular to the surface of the package substrate 110, one surface of the surface layer 132 may be in contact with the chip pad 220P and another surface thereof may be in contact with the filling layer 131. Based on the first direction DI perpendicular to the surface of the package substrate 110, the surface layer 132 alone may be disposed between the chip pads 220P and the filling layer 131.

In an example, the connection structures 130 may penetrate the organic layer 120 in the first direction D1 perpendicular to the surface of the package substrate 110. Accordingly, the connection structures 130 may electrically connect the package substrate 110 and the chip pads 220P.

In an example, in the connection structures 130, a length based on the first direction D1 perpendicular to the surface of the package substrate 110 may be determined depending on a vertical distance (e.g., a distance in the first direction) between the stacked semiconductor chip 220 and the surface of the package substrate 110.

In an example, the connection structures 130 may be provided in plural. The plurality of connection structures 130 may have different lengths in the first direction D1 perpendicular to the surface of the package substrate 110. For example, the connection structures 130 may include a first connection structure 130a and a second connection structure 130b of which lengths in the first direction D1 perpendicular to the surface of the package substrate 110 are different from each other. For example, the connection structures 130 may include the first connection structure 130a, the second connection structure 130b, and a third connection structure 130c of which lengths in the first direction D1 perpendicular to the surface of the package substrate 110 are different from each other. Here, each of the first connection structure 130a, the second connection structure 130b, and the third connection structure 130c may be plural in number.

In an example, the first connection structure 130a may include a first filling layer 131a connected to the first chip pad 221P of the first stacked semiconductor chip 221 and a first surface layer 132a surrounding at least a portion of the first filling layer 131a. The second connection structure 130b may include a second filling layer 131b connected to the second chip pad 222P of the second stacked semiconductor chip 222 and a second surface layer 132b surrounding at least a portion of the second filling layer 131b. The third connection structure 130c may include a third filling layer 131c connected to the third chip pad 223P of the third stacked semiconductor chip 223 and a third surface layer 132c surrounding at least a portion of the third filling layer 131c.

In an example, a length of the first connection structure 130a in the first direction D1 may be shorter than a length of the second connection structure 130b in the first direction D1. In addition, the length of the second connection structure 130b in the first direction D1 may be shorter than a length of the third connection structure 130c in the first direction D1.

In an example, the first connection structure 130a and the second connection structure 130b may be spaced from each other in the second direction D2 parallel to the surface of the package substrate 110, and may extend parallel to each other in the first direction D1. In addition, the first connection structure 130a, the second connection structure 130b, and the third connection structure 130c may be spaced from each other in the second direction D2 parallel to the surface of the package substrate 110, and may extend parallel to each other in the first direction D1.

In an example, the first connection structure 130a and the second connection structure 130b may be disposed to be spaced apart from each other by a predetermined distance in the second direction D2 parallel to the surface of the package substrate 110. In addition, the first connection structure 130a, the second connection structure 130b, and the third connection structure 130c may be disposed to be spaced apart from each other by a predetermined distance in the second direction D2 parallel to the surface of the package substrate 110.

The number of the plurality of connection structures (e.g., the first connection structure 130a, the second connection structure 130b, and the third connection structure 130c described above is not particularly limited and may be determined depending on the number of the stacked semiconductor chip 220 that are disposed. In addition, when four or more connection structures 130 are disposed, the above descriptions may also be referenced.

In an example, the organic layer 120 may have a step structure. For example, the organic layer 120 may be divided into at least two portions with different thicknesses from each other. Here, the thickness may refer to a length in the first direction D1 perpendicular to the surface of the package substrate 110. For example, the organic layer 120 may include a first portion 121 in which the first connection structure 130a is embedded and that is disposed between the first stacked semiconductor chip 221 and the package substrate 110, and a second portion 122 in which the second connection structure 130b is embedded and that is disposed between the second stacked semiconductor chip 222 and the package substrate 110. In addition, the organic layer 120 may include a third portion 123 in which the third connection structure 130c is embedded and that is disposed between the third stacked semiconductor chip 223 and the package substrate 110, in addition to the first portion 121 and the second portion 122 described above. Here, a thickness of the first portion 121 may be different from a thickness of the second portion 122, and specifically, the thickness of the first portion 121 may be less than the thickness of the second portion 122. Further, each thickness of the first portion 121, the second portion 122, and the third portion 123 may be different, and specifically, the thickness of the first portion 121 may be less than the thickness of the second portion 122 and the thickness of the second portion 122 may be less than the thickness of the third portion 123.

In an example, in the first direction DI perpendicular to the surface of the package substrate 110, an upper surface 121US of the first portion and an upper surface 210US of the base semiconductor chip may be disposed to be flush. In addition, in the first direction D1 perpendicular to the surface of the package substrate 110, an upper surface 122US of the second portion and an upper surface 221US of the first stacked semiconductor chip 221 may be disposed to be flush. In addition, in the first direction D1 perpendicular to the surface of the package substrate 110, an upper surface 123US of the third portion and an upper surface 222US of the second stacked semiconductor chip 222 may be disposed to be flush. In these manners, stacking the base semiconductor chip 210 and the stacked semiconductor chips 220 may prevent a bubble from harming the package substrate 110.

In an example, when viewed in the first direction D1 perpendicular to the surface of the package substrate 110, the connection structures 130 and the chip pad 220P may be at least partially overlap with each other.

In an example, when viewed in the first direction D1 perpendicular to the surface of the package substrate 110, the connection structures 130 and the base pad 210P may not overlap with each other. The base pad 210P may be spaced apart from the connection structures 130 in the second direction D2 parallel to the surface of the package substrate 110.

In an example, in the second direction D2 parallel to the surface of the package substrate 110, the organic layer 120 may be disposed to be spaced apart from the base semiconductor chip 210 and the stacked semiconductor chips 220 by a predetermined distance. Specifically, in the second direction D2, the first portion 121 of the organic layer 120 may be disposed to be spaced apart from the base semiconductor chip 210 by a predetermined distance. In addition, in the second direction D2, the second portion 122 of the organic layer 120 may be disposed to be spaced apart from the base semiconductor chip 210 and the first stacked semiconductor chip 221 by a predetermined distance. In addition, in the second direction D2, the third portion 123 of the organic layer 120 may be disposed to be spaced apart from the base semiconductor chip 210, the first stacked semiconductor chip 221, and the second stacked semiconductor chip 222 by a predetermined distance.

The semiconductor package 10 according to an example embodiment of the present disclosure may further include a molding film 500 covering the base semiconductor chip 210 and the stacked semiconductor chips 220. The molding film 500 may include, for example, epoxy molding compound (EMC).

In an example, the molding film 500 may fill a space between the organic layer 120 and the base semiconductor chip 210 in the second direction D2 parallel to the surface of the package substrate 110. In addition, the molding film 500 may fill a space between the organic layer 120 and the stacked semiconductor chips 220 in the second direction D2 parallel to the surface of the package substrate 110. Specifically, in the second direction D2, the molding film 500 may fill a space between the first portion 121 of the organic layer 120 and the base semiconductor chip 210, a space between the second portion 122 of the organic layer 120 and each of the base semiconductor chip 210 and the first stacked semiconductor chip 221, and a space between the third portion 123 of the organic layer 120 and each of the base semiconductor chip 210, the first stacked semiconductor chip 221, and the second stacked semiconductor chip 222. Accordingly, a structural stability of the semiconductor package 10 may be improved.

In the semiconductor package 10 according to an example embodiment of the present disclosure, the connection structures 130 may have a constant length in the second direction D2 parallel to the surface of the package substrate 110. Here, being constant may mean being substantially constant.

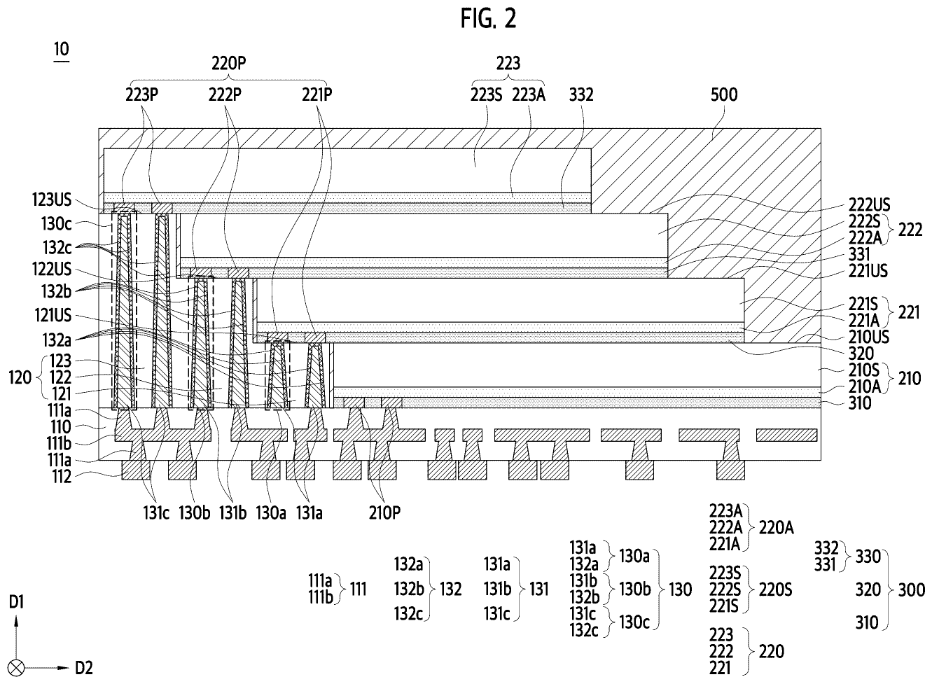

FIG. 2 is a cross-sectional view showing the semiconductor package 10 according to a second example embodiment of the present disclosure.

In the semiconductor package 10 according to an example embodiment of the present disclosure, as a distance from the package substrate 110 in the first direction D1 perpendicular to the surface of the package substrate 110 increases, the connection structures 130 may gradually decrease in width in the second direction D2 parallel to the surface of the package substrate 110. Other aspects of the connection structures 130 may be understood based on the descriptions thereof made with reference to FIG. 1. The above shape may make it easy to form the trench (see trench TR of FIGS. 10 and 19) to be described below.

Hereinafter, a method of fabricating the semiconductor package 10 according to an example embodiment of the present disclosure is described. The above descriptions of the semiconductor package 10 may be referenced for describing the method of fabricating the semiconductor package 10 unless contradicted.

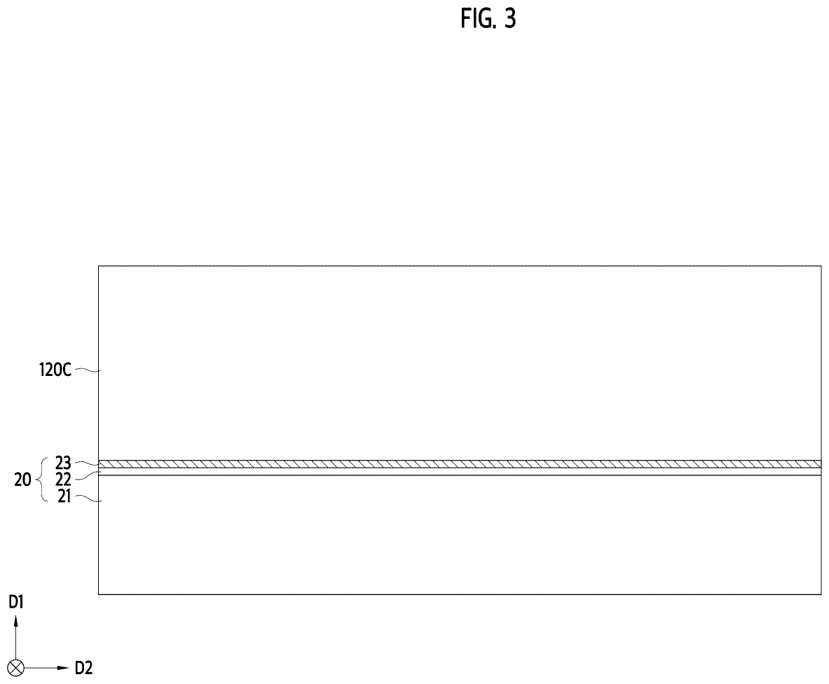

FIG. 3 is a cross-sectional view showing a process of applying an organic layer precursor 120C on a base layer 20 in a method of fabricating the semiconductor package 10 according to an example embodiment of the present disclosure.

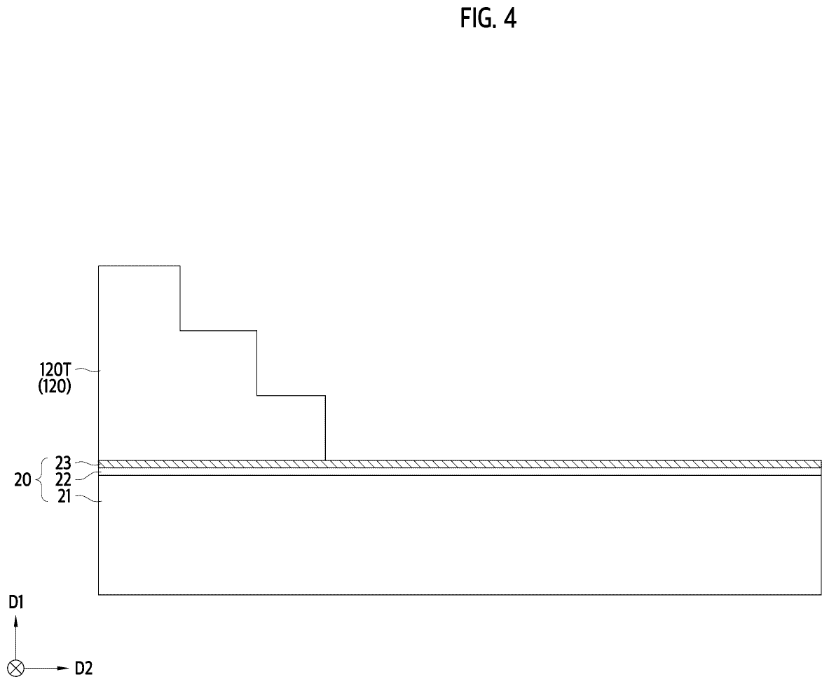

In an example, the base layer 20 is not particularly limited and may include a glass substrate 21. In addition, the base layer 20 may include a release layer 22 disposed above the glass substrate 21. Further, the base layer 20 may include a barrier metal layer 23 disposed above the release layer 22. In an example, the organic layer precursor 120C may be disposed above the barrier metal layer 23. The barrier metal layer 23 may protect the release layer 22 and the glass substrate 21 when a step-structured organic layer (see step-structured organic layer 120T of FIG. 4) is formed later, which may prevent failure occurrence due to damage to the release layer 22 and the glass substrate 21 in the following processes.

FIG. 4 is a cross-sectional view showing forming the step-structured organic layer 120T with the organic layer precursor 120C in a method of fabricating the semiconductor package 10 according to an example embodiment of the present disclosure.

In an example, the method of fabricating the semiconductor package 10 may include forming the step-structured organic layer 120T by exposing the organic layer precursor 120C formed above the base layer 20. The step-structured organic layer 120T is described for describing the method of fabricating the semiconductor package 10 and may be identical to the organic layer 120 described above.

In an example, the organic layer precursor 120C may be exposed using at least one from among a phase shift mask (PSM) and nano-imprinting lithography (NIL). By using these manners, the step-structured organic layer 120T divided into a plurality of portions with different lengths in the first direction DI perpendicular to a surface of the base layer 20 may be formed.

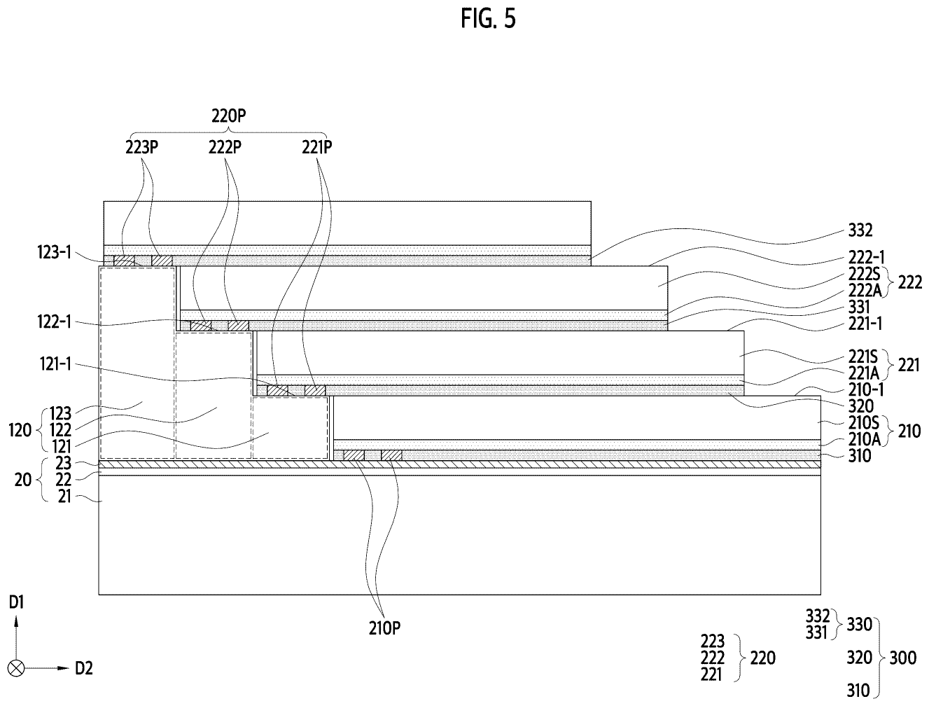

FIG. 5 is a cross-sectional view showing stacking the base semiconductor chip 210 and the stacked semiconductor chips 220 on the package substrate 110 in a method of fabricating the semiconductor package 10 according to an example embodiment of the present disclosure.

In an example, the method of fabricating the semiconductor package 10 may include disposing the base semiconductor chip 210 including the base pad 210P above the base layer 20. In addition, the method of fabricating the semiconductor package 10 may include disposing the stacked semiconductor chips 220 including the chip pads 220P above the base semiconductor chip 210.

In an example, in the method of fabricating the semiconductor package 10, when stacking the base semiconductor chip 210 and the stacked semiconductor chips 220, the bonding layers 300 described above may be used. Specifically, the method of fabricating the semiconductor package 10 may include forming the base bonding layer 310 above the base layer 20 and disposing the base semiconductor chip 210 above the base bonding layer 310. In addition, the method of fabricating the semiconductor package 10 may include forming the connection bonding layer 320 above the base bonding layer 310 and disposing the stacked semiconductor chips 220 above the connection bonding layer 320. In addition, when the plurality of stacked semiconductor chips 220 are disposed, the method of fabricating the semiconductor package 10 may include forming the connection bonding layer 320 above the base semiconductor chip 210 and disposing the first stacked semiconductor chip 221 above the connection bonding layer 320 and forming the chip bonding layer 330 above the first stacked semiconductor chip 221, and additionally disposing the second stacked semiconductor chip 222 above the chip bonding layer 330.

In an example, in the method of fabricating the semiconductor package 10, the base pad 210P may be embedded in the base bonding layer 310, and the chip pad 220P may be embedded in the connection bonding layer 320 or the chip bonding layer 330.

In an example, in the method of fabricating the semiconductor package 10, the base semiconductor chip 210 and the stacked semiconductor chips 220 may be stacked on the package substrate 110 so that the base pad 210P and the chip pad 220P are not overlapping with each other when viewed in the first direction DI perpendicular to the surface of the base layer 20.

In an example, in the method of fabricating the semiconductor package 10, the plurality of stacked semiconductor chips 220 may be disposed, and in this case, the plurality of stacked semiconductor chips 220 may be stacked so that each chip pad 220P are not overlapping with each other when viewed in the first direction D1 perpendicular to the surface of the base layer 20.

In an example, the method of fabricating the semiconductor package 10 may include disposing the base semiconductor chip 210 in order for the base pad 210P to be in contact with the base layer 20. In addition, the method of fabricating the semiconductor package 10 may include disposing the stacked semiconductor chips 220 in order for the chip pads 220P to be in contact with the organic layer 120. In other words, the base semiconductor chip 210 and the stacked semiconductor chips 220 may be disposed in order for the base semiconductor active layer 210A of the base semiconductor chip 210 and the stacked semiconductor active layer 220A of the stacked semiconductor chips 220 to face the base layer 20 in the first direction D1 perpendicular to the surface of the base layer 20. This manner may be referred to as face-down.

In an example, in the method of fabricating the semiconductor package 10, the organic layer 120 may be divided into at least two portions with different thicknesses and may be divided into the first portion 121, the second portion 122, and the third portion 123 in an order starting from the least thickest. In an example, the method of fabricating the semiconductor package 10 may include disposing a first surface 121-1 of the first portion and a first surface 210-1 of the base semiconductor chip 210 to be flush. Further, in an example, the method of fabricating the semiconductor package 10 may include disposing a first surface 122-1 of the second portion and a first surface 221-1 of the first stacked semiconductor chip 221 to be flush. Further, in an example, the method of fabricating the semiconductor package 10 may include disposing a first surface 123-1 of the third portion and a first surface 222-1 of the second stacked semiconductor chip 222 to be flush. Here, the first surface may indicate an uppermost surface in the positive first direction D1 of FIG. 5, and may be an upper surface. According to embodiments, a second surface may indicate an uppermost surface in the negative first direction D1 of FIG. 5 and may be a bottom surface. In these manners, stacking the base semiconductor chip 210 and the stacked semiconductor chips 220 may prevent a bubble from harming the package substrate 110.

In an example, in the method of fabricating the semiconductor package 10, in the second direction D2 parallel to the surface of the base layer 20, the organic layer 120 may be disposed to be spaced apart from the base semiconductor chip 210 and the stacked semiconductor chips 220 by a predetermined distance.

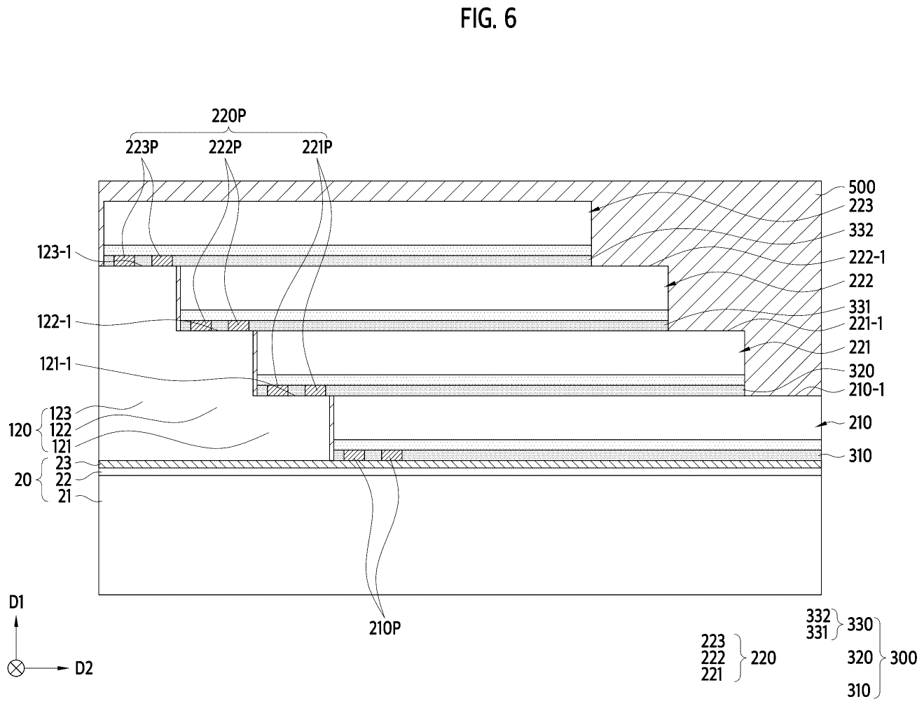

FIG. 6 is a cross-sectional view showing forming the molding film 500 in a method of fabricating the semiconductor package 10 according to an example embodiment of the present disclosure. The molding film 500 may cover the base semiconductor chip 210 and the stacked semiconductor chips 220.

In an example, in the method of fabricating the semiconductor package 10, the molding film 500 may fill a space between the organic layer 120 and the base semiconductor chip 210 in the second direction D2 parallel to the surface of the base layer 20. In addition, the molding film 500 may fill a space between the organic layer 120 and the stacked semiconductor chips 220 in the second direction D2 parallel to the surface of the base layer 20. Specifically, in the second direction D2, the molding film 500 may fill a space between the first portion 121 of the organic layer 120 and the base semiconductor chip 210, a space between the second portion 122 of the organic layer 120 and each of the base semiconductor chip 210 and the first stacked semiconductor chip 221, and a space between the third portion 123 of the organic layer 120 and each of the base semiconductor chip 210, the first stacked semiconductor chip 221, and the second stacked semiconductor chip 222.

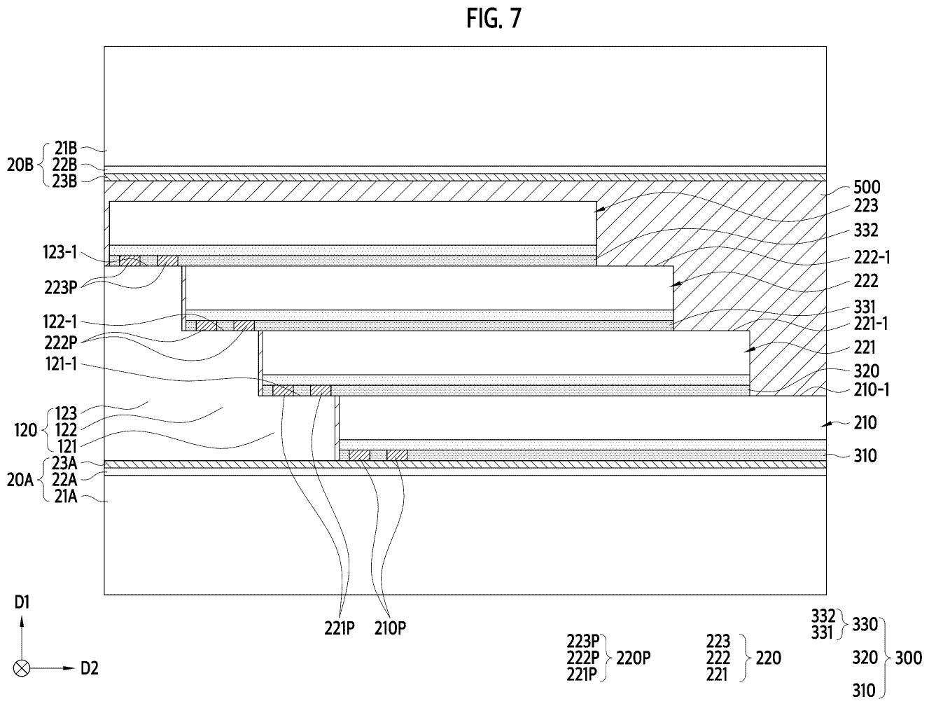

FIG. 7 is a cross-sectional view showing disposing a carrier layer 20B above the molding film 500 in a method of fabricating the semiconductor package 10 according to an example embodiment of the present disclosure. Here, the base layer 20A may be the base layer 20, the glass substrate 21A may be the glass substrate 21, the release layer 22A may be the release layer 22A, and the barrier metal layer 23 A may be the barrier metal layer 23.

In an example, the carrier layer 20B is not particularly limited and may include a glass substrate 21B. In addition, the carrier layer 20B may include a release layer 22B disposed below the glass substrate 21B. Further, the carrier layer 20B may include a barrier metal layer 23B disposed below the release layer 22B. In an example, specifically, the method of fabricating the semiconductor package 10 may include disposing the carrier layer 20B in order for the barrier metal layer 23B of the carrier layer 20B to be disposed above the molding film 500.

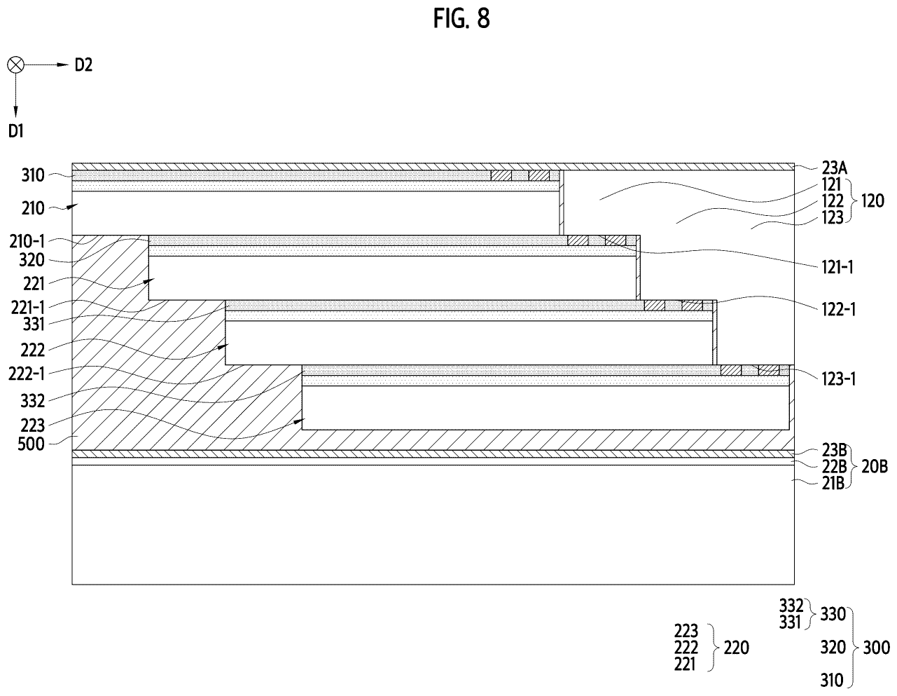

FIG. 8 is a cross-sectional view showing removing a portion of the base layer 20A after a flip in a method of fabricating the semiconductor package 10 according to an example embodiment of the present disclosure.

In an example, the method of fabricating the semiconductor package 10 may include performing a flip so that the positive first direction D1 perpendicular to the surface of the base layer 20A is flipped 180 degrees. In addition, the method of fabricating the semiconductor package 10 may include removing a portion of the base layer 20A in a flipped state and, specifically, removing the glass substrate 21A along with the release layer 22A of the base layer 20A. In other words, the method of fabricating the semiconductor package 10 may include removing the release layer 22A and the glass substrate 21A which are the remaining elements of the base layer 20A while leaving the barrier metal layer 23A of the base layer 20A.

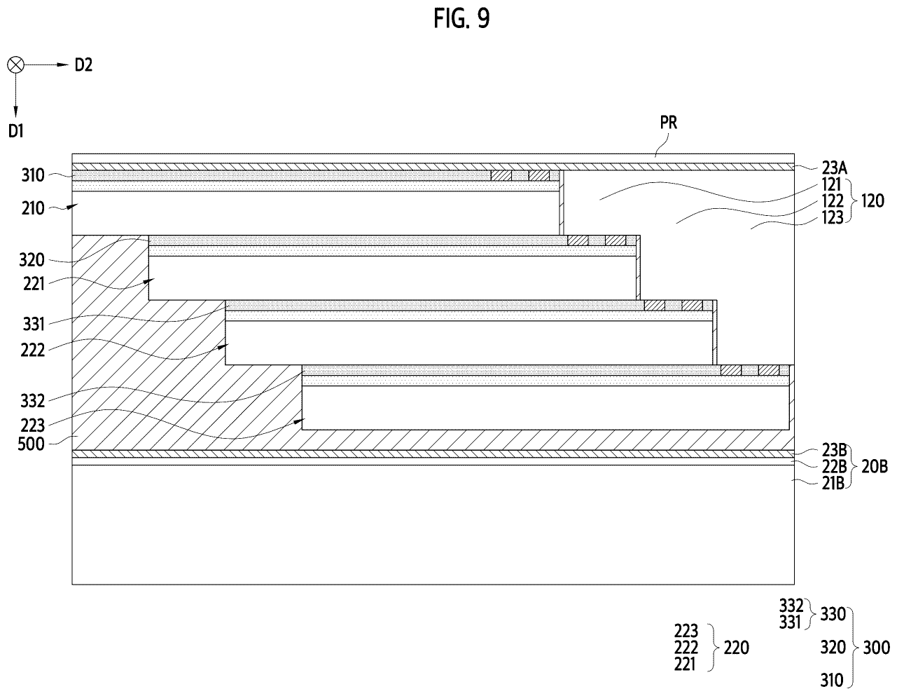

FIG. 9 is a cross-sectional view showing applying a photoresist PR in a method of fabricating the semiconductor package 10 according to an example embodiment of the present disclosure.

In an example, the method of fabricating the semiconductor package 10 may include applying the photoresist PR on one surface of the barrier metal layer 23A of the base layer 20A. The photoresist PR may be applied so that an entire surface of the barrier metal layer 23A is covered.

FIG. 10 is a cross-sectional view showing forming the trench TR by etching the organic layer 120 in a method of fabricating the semiconductor package 10 according to the first example embodiment of the present disclosure.

In an example, the method of fabricating the semiconductor package 10 may include forming the trench TR by etching the organic layer 120 along the first direction D1.

In an example, in the method of fabricating the semiconductor package 10, the trench TR may have a constant length in the second direction D2 parallel to the surface of the carrier layer 20B. Here, the first direction DI perpendicular to the surface of the carrier layer 20B is identical to the first direction D1 perpendicular to the surface of the base layer 20A described above. In addition, the second direction D2 parallel to the surface of the carrier layer 20B is identical to the second direction D2 parallel to the surface of the base layer 20A described above.

In an example, the method of fabricating the semiconductor package 10 may include etching the organic layer 120 along the first direction DI perpendicular to the surface of the carrier layer 20B until the chip pad 220P is exposed by the trench TR.

In an example, the method of fabricating the semiconductor package 10 may include etching the organic layer 120 along the first direction D1 perpendicular to the surface of the carrier layer 20B so that, the trench TR has a constant length in the second direction D2 parallel to the surface of the carrier layer 20B, as described above.

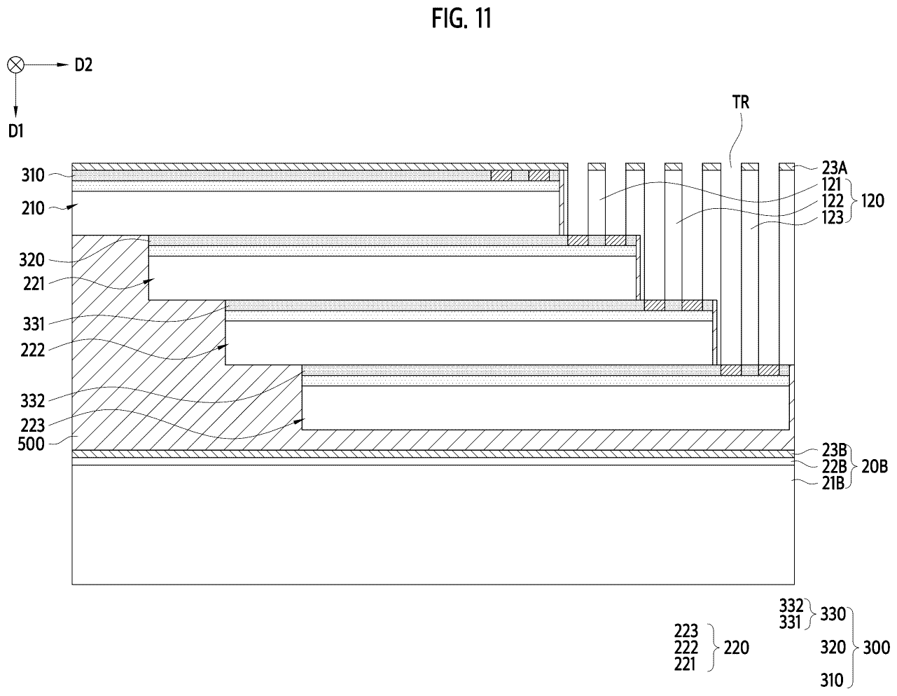

FIG. 11 is a cross-sectional view showing removing the photoresist PR in a method of fabricating the semiconductor package 10 according to the first example embodiment of the present disclosure.

In an example, the method of fabricating the semiconductor package 10 may include removing the remaining portion of the photoresist PR disposed above the barrier metal layer 23A of the base layer 20A using a cleaning liquid or the like.

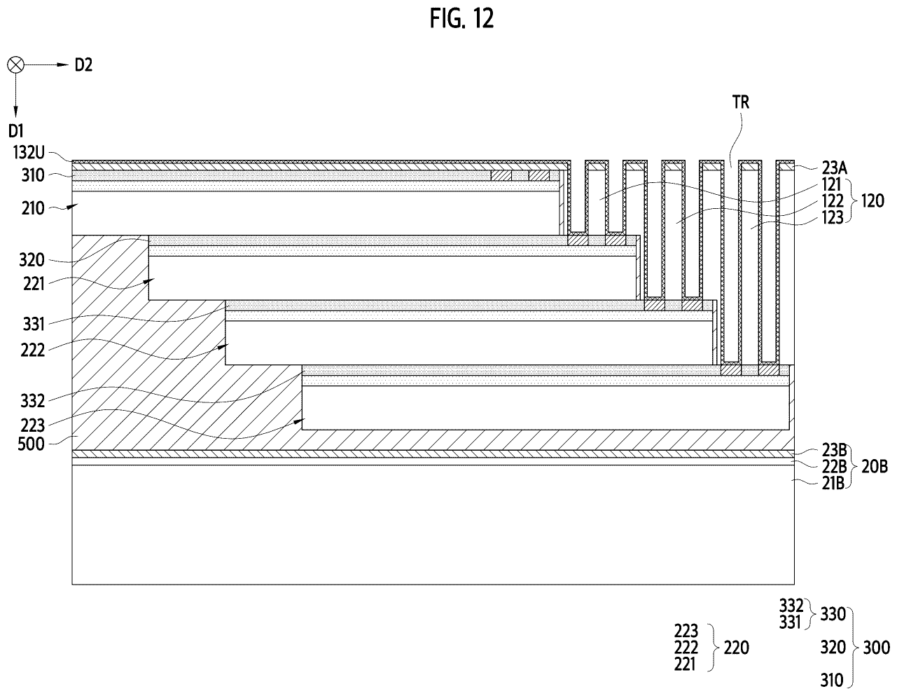

FIG. 12 is a cross-sectional view showing forming a seed metal layer 132U in a method of fabricating the semiconductor package 10 according to the first example embodiment of the present disclosure.

In an example, in the method of fabricating the semiconductor package 10, the seed metal layer 132U may be formed at least on a surface of the trench TR. A manner of forming the seed metal layer 132U is not particularly limited, and deposition (e.g., physical vapor deposition (PVD), chemical vapor deposition (CVD), or electroless deposition (ELD)) may be applied thereto.

In an example, the seed metal layer 132U may include one or more selected from among titanium (Ti), chrome (Cr), and copper alloy. In addition, the seed metal layer 132U may become the surface layer 132 described above.

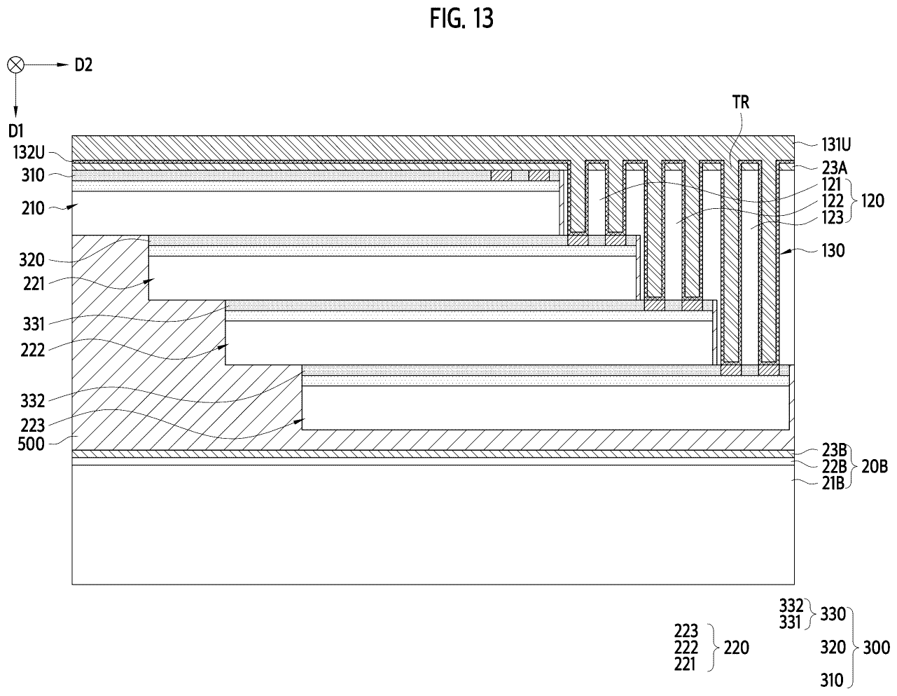

FIG. 13 is a cross-sectional view showing forming a connection layer 131U in a method of fabricating the semiconductor package 10 according to the first example embodiment of the present disclosure.

In an example, the method of fabricating the semiconductor package 10 may include forming the connection layer 131U on the seed metal layer 132U and may include forming the connection structures 130 as the connection layer 131U fills the trench TR. Specifically, the connection layer 131U filling the trench TR may become the filling layer 131 described above, and eventually, the connection structures 130 may be formed.

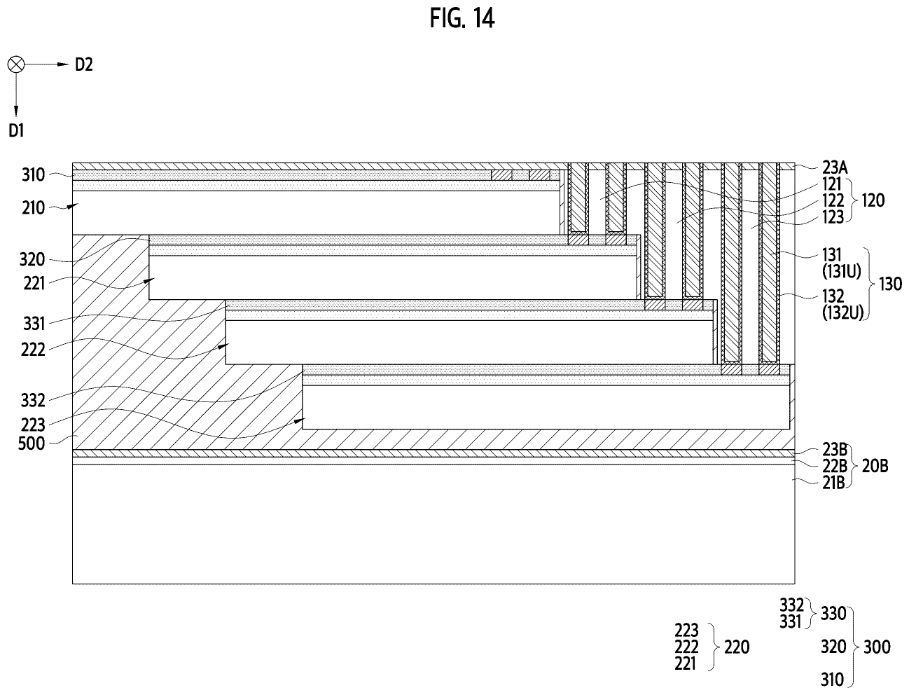

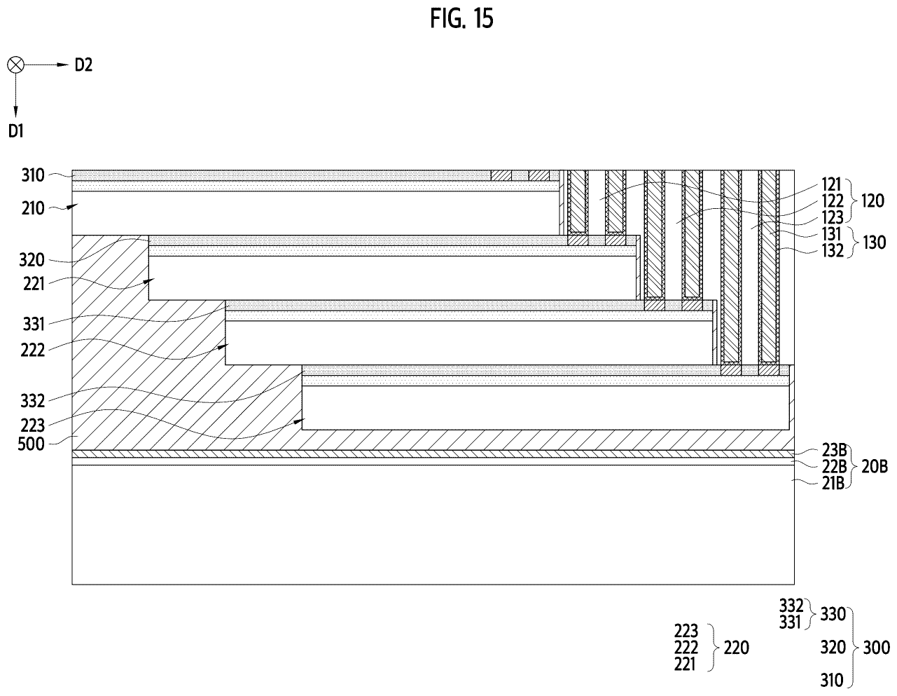

FIG. 14 is a cross-sectional view showing removing a remainder excluding the seed metal layer 132U and the connection layer 131U disposed within the trench TR in a method of fabricating the semiconductor package 10 according to the first example embodiment of the present disclosure. FIG. 15 is a cross-sectional view showing removing the barrier metal layer 23A through a polishing process in a method of fabricating the semiconductor package 10 according to the first example embodiment of the present disclosure.

In an example, in the method of fabricating the semiconductor package 10, the seed metal layer 132U and the connection layer 131U disposed within the trench TR may become the surface layer 132 and the filling layer 131 described above, respectively. The method of fabricating the semiconductor package 10 may include removing the remainder excluding the seed metal layer 132U and the connection layer 131U disposed within the trench TR. In addition, the method of fabricating the semiconductor package 10 may include removing the barrier metal layer 23A of the base layer 20A. For removing those, chemical mechanical polishing (CMP) may be used.

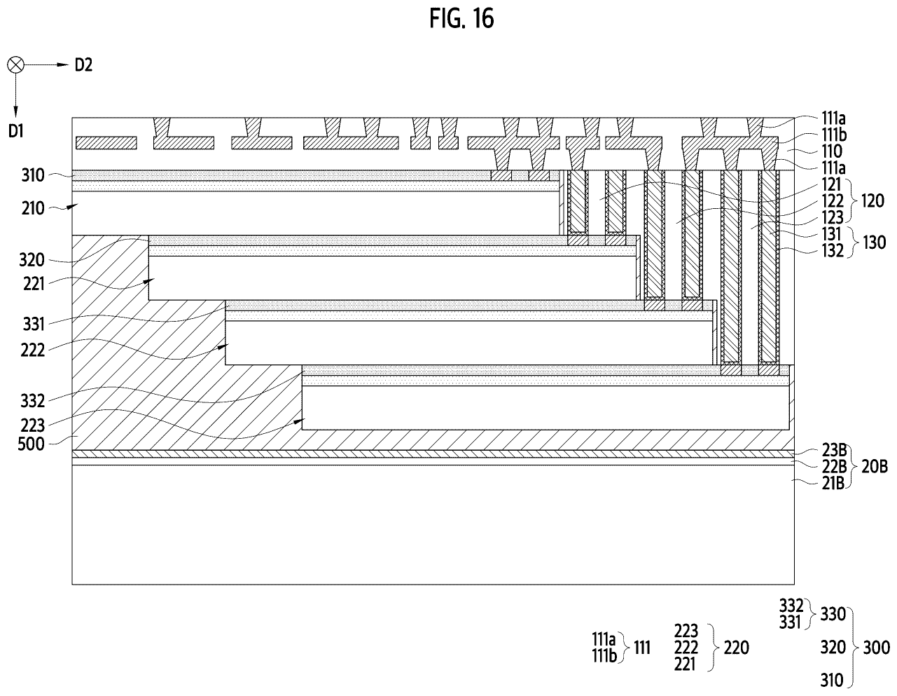

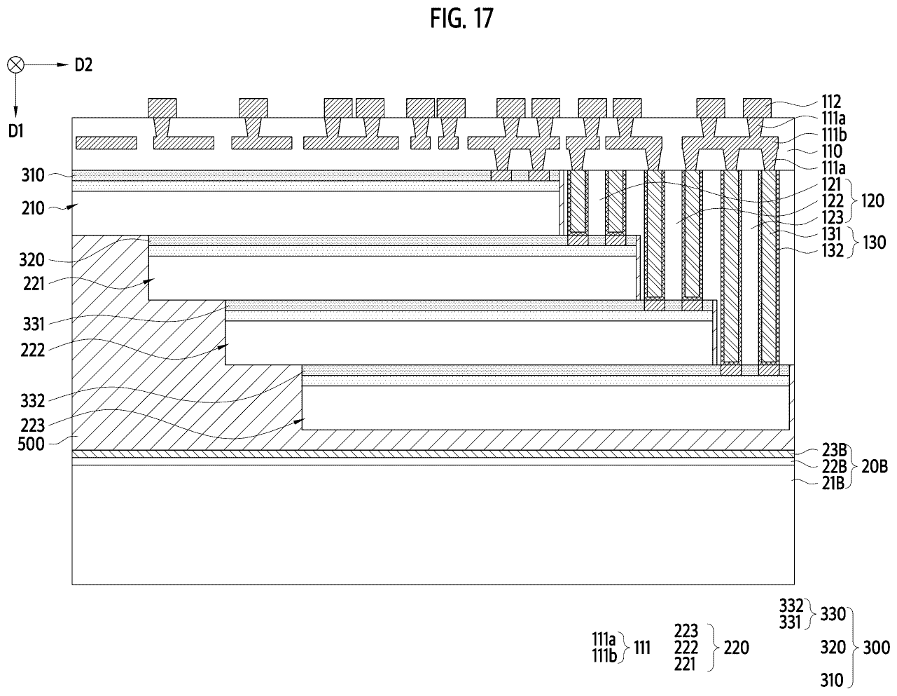

FIG. 16 is a cross-sectional view showing forming a redistribution layer that arranges wiring in the package substrate 110 in a method of fabricating the semiconductor package 10 according to the first example embodiment of the present disclosure. FIG. 17 is a cross-sectional view showing disposing the external connection terminal 112 in a method of fabricating the semiconductor package 10 according to the first example embodiment of the present disclosure.

In an example, the method of fabricating the semiconductor package 10 may include disposing the package substrate 110 on a surface where the barrier metal layer 23A described above is removed. The method of fabricating the semiconductor package 10 may include forming the redistribution layer by arranging wiring on the package substrate 110 and, specifically, may include forming the wiring structure 111 including the wiring pattern 111a and the connection pattern 111b.

In an example, the method of fabricating the semiconductor package 10 may include contacting the wiring pattern 111a with the base pad 210P and the filling layer 131. In addition, the method of fabricating the semiconductor package 10 may include overlapping the filling layer 131 and the chip pad 220P at least partially in the first direction D1 perpendicular to the surface of the package substrate 110 so that the wiring pattern 111a and the chip pad 220P may be electrically connected.

With reference to FIG. 17, in an example, the method of fabricating the semiconductor package 10 may include connecting the external connection terminal 112 to the wiring structure 111.

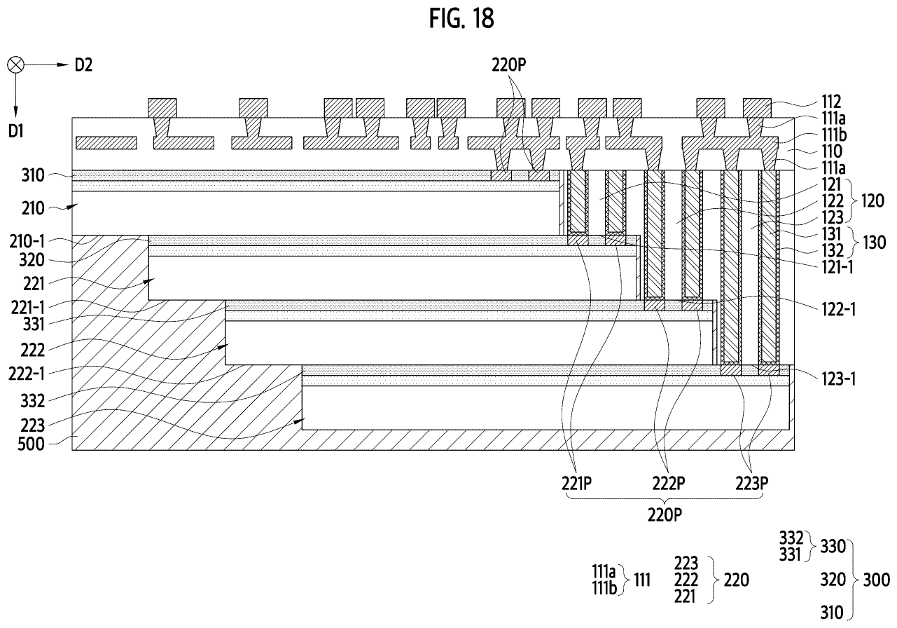

FIG. 18 is a cross-sectional view showing a state before a flip of the semiconductor package 10 in a method of fabricating the semiconductor package 10 according to the first example embodiment of the present disclosure.

In an example, the method of fabricating the semiconductor package 10 may include completing the semiconductor package 10 by removing the carrier layer 20B and flipping the semiconductor package 10 again. In the method of fabricating the semiconductor package 10, the carrier layer 20B may be removed and then the flip may be performed, or the flip may be performed and then the carrier layer 20B may be removed.

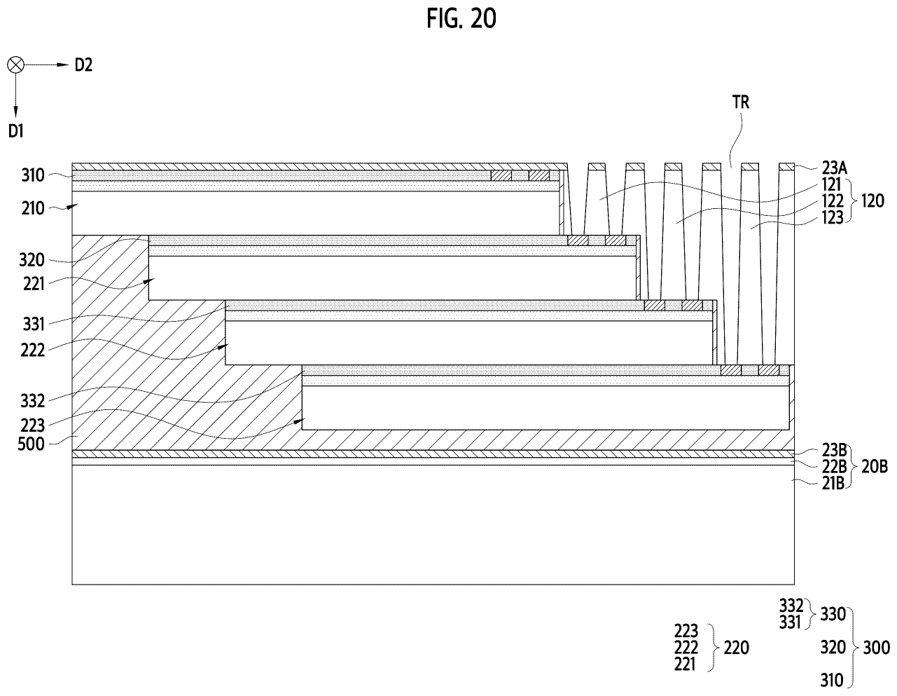

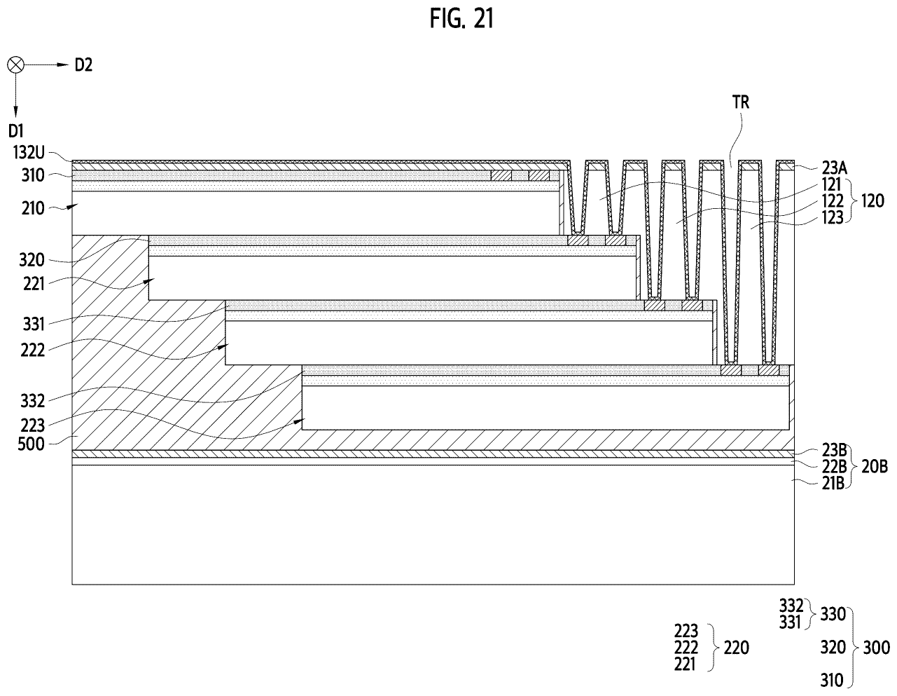

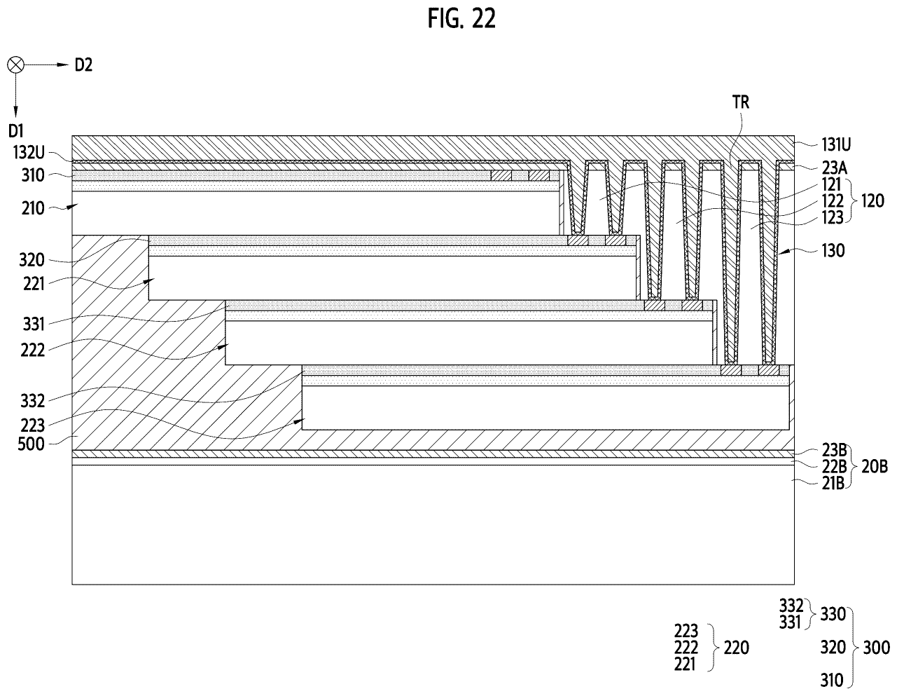

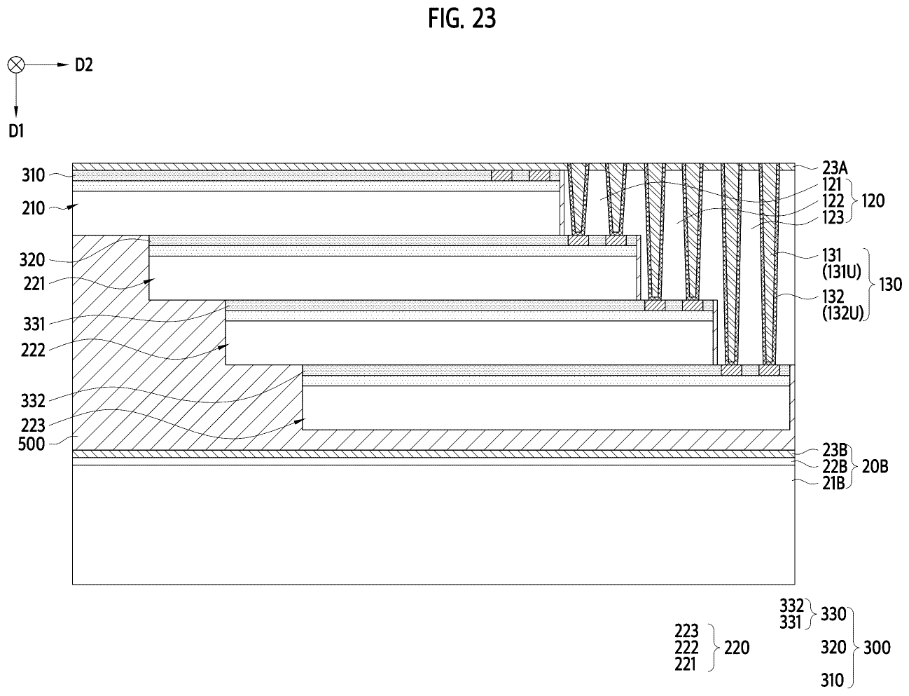

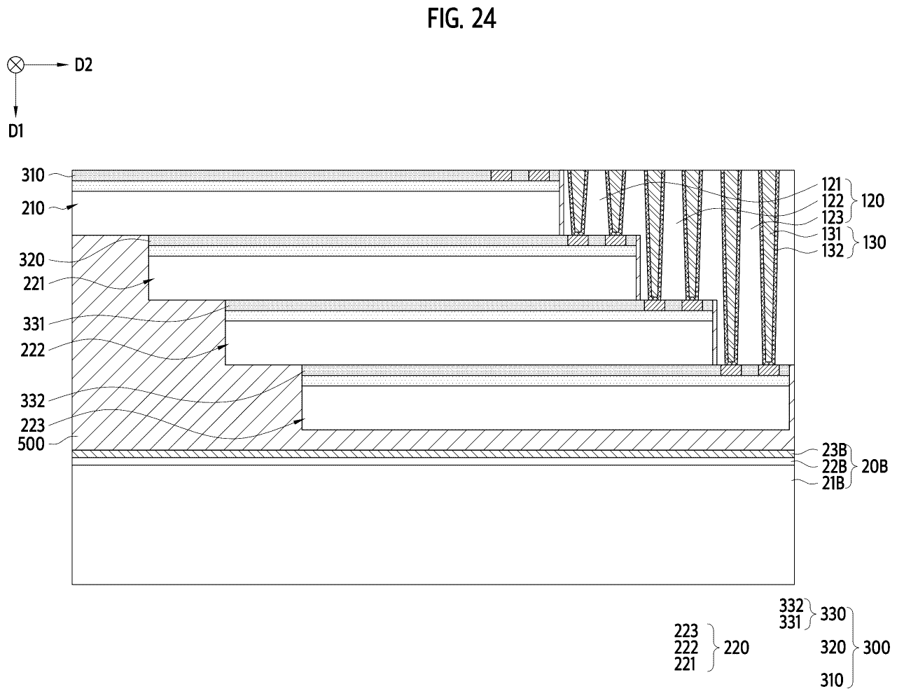

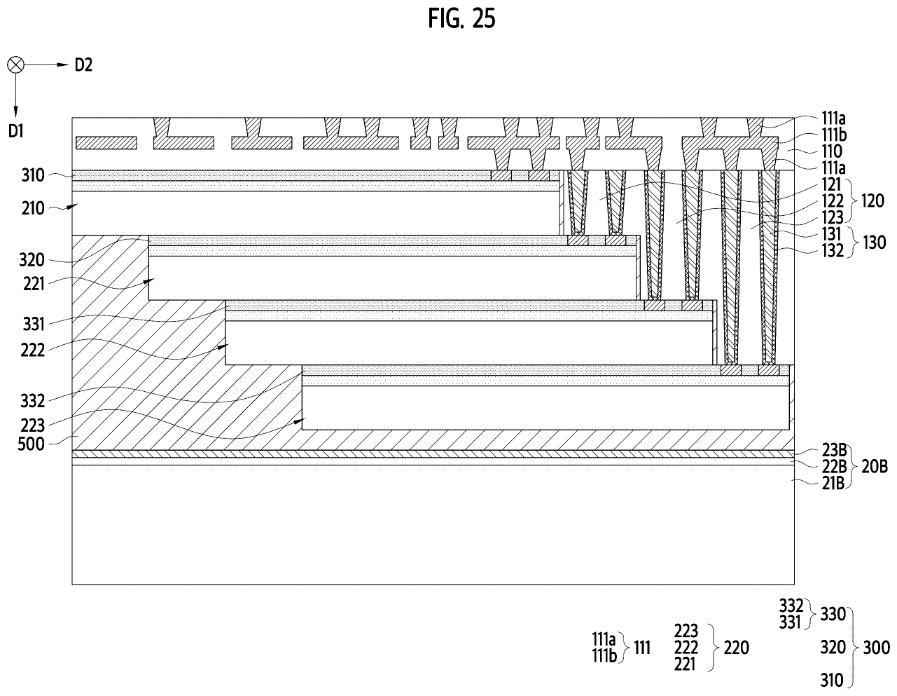

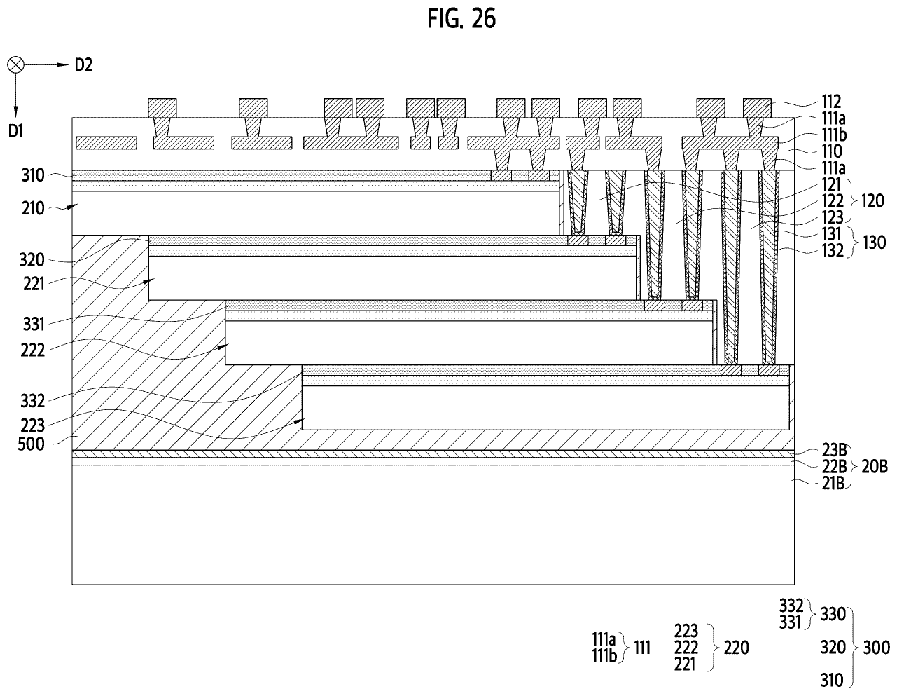

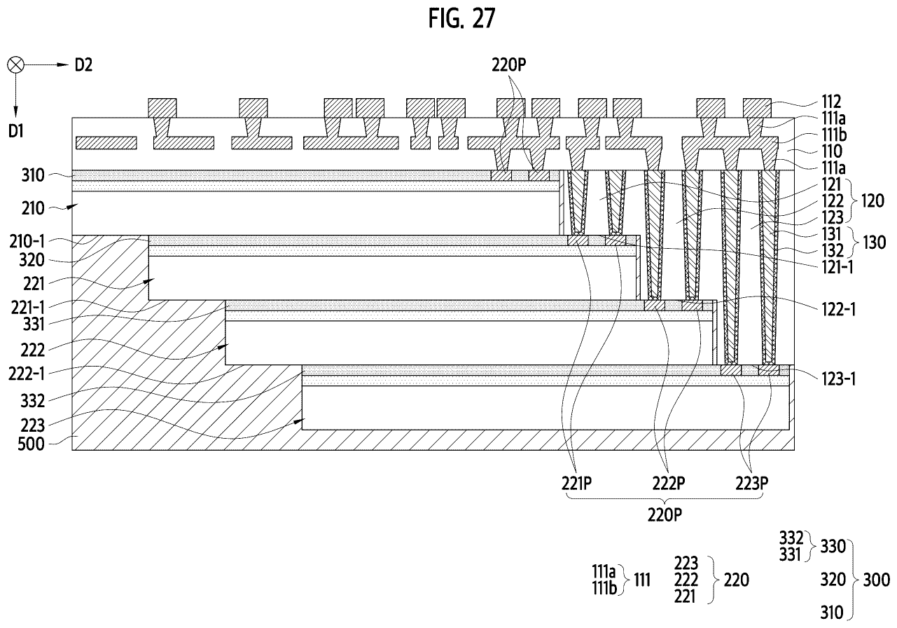

FIG. 19 is a cross-sectional view showing forming the trench TR by etching the organic layer 120 in a method of fabricating the semiconductor package 10 according to the second example embodiment of the present disclosure. FIG. 20 is a cross-sectional view showing removing the photoresist PR in a method of fabricating the semiconductor package 10 according to the second example embodiment of the present disclosure. FIG. 21 is a cross-sectional view showing forming the seed metal layer 132U in a method of fabricating the semiconductor package 10 according to the second example embodiment of the present disclosure. FIG. 22 is a cross-sectional view showing forming the connection layer 131U in a method of fabricating the semiconductor package 10 according to the second example embodiment of the present disclosure. FIG. 23 is a cross-sectional view showing removing the remainder excluding the seed metal layer 132U and the connection layer 131U disposed within the trench TR in a method of fabricating the semiconductor package 10 according to the second example embodiment of the present disclosure. FIG. 24 is a cross-sectional view showing removing the barrier metal layer 23A through a polishing process in a method of fabricating the semiconductor package 10 according to the second example embodiment of the present disclosure. FIG. 25 is a cross-sectional view showing forming a redistribution layer that arranges wiring in the package substrate 110 in a method of fabricating the semiconductor package 10 according to the second example embodiment of the present disclosure. FIG. 26 is a cross-sectional view showing disposing the external connection terminal 112 in a method of fabricating the semiconductor package 10 according to the second example embodiment of the present disclosure. FIG. 27 is a cross-sectional view showing a state before a flip of the semiconductor package 10 in a method of fabricating the semiconductor package 10 according to the second example embodiment of the present disclosure.

FIGS. 19 to 27 merely have a difference in a shape of the trench TR compared to the method of fabricating the semiconductor package 10 illustrated in the FIGS. 10 to 18 and thus the descriptions regarding FIGS. 10 to 18 may be referenced unless contradicted.

In an example, in the method of fabricating the semiconductor package 10, in the first direction D1, perpendicular to a surface of the carrier layer 20B, towards the carrier layer 20B, the trench TR may gradually decrease in width in the second direction D2 parallel to the surface of the carrier layer 20B.

While non-limiting example embodiments of the present disclosure are described above with reference to the accompanying drawings, the present disclosure is not limited to the example embodiments and may be implemented in various different forms, and it will be apparent to those of ordinary skill in the art to which the present disclosure pertains that other specific forms may be implemented without departing from the spirit and scope of the present disclosure. Therefore, the example embodiments described above are examples in every aspect and are not to be construed as limiting.

What is claimed is:

1. A semiconductor package comprising:
a package substrate;
a base semiconductor chip above the package substrate, the base semiconductor chip comprising a base pad in contact with the package substrate;
at least one stacked semiconductor chip above the base semiconductor chip, the at least one stacked semiconductor chip comprising a chip pad connected to the package substrate; and
an organic layer between the package substrate and the at least one stacked semiconductor chip in a first direction perpendicular to a surface of the package substrate; and
at least one connection structure in the organic layer, the at least one connection structure connecting the package substrate and the chip pad of the at least one stacked semiconductor chip,
wherein the at least one connection structure comprises a filling layer and a surface layer surrounding at least a portion of the filling layer.

2. The semiconductor package of claim 1, wherein, the base pad and the chip pad do not overlap each other in the first direction.

3. The semiconductor package of claim 1, wherein the base pad is spaced apart from the at least one connection structure in a second direction parallel to the surface of the package substrate.

4. The semiconductor package of claim 1, wherein the at least one connection structure penetrates the organic layer in the first direction and connects the package substrate and the chip pad.

5. The semiconductor package of claim 1, wherein the filling layer comprises copper (Cu).

6. The semiconductor package of claim 1, wherein the at least one connection structure and the chip pad at least partially overlap with each other in the first direction.

7. The semiconductor package of claim 1, wherein one surface of the surface layer, that faces in a second direction parallel to the surface of the package substrate, is in contact with the organic layer and another surface of the surface layer, opposite of the one surface, is in contact with the filling layer.

8. The semiconductor package of claim 1, wherein the surface layer comprises at least one from among titanium (Ti), chrome (Cr), and copper alloy.

9. The semiconductor package of claim 1, wherein the organic layer is spaced apart from the base semiconductor chip and the at least one stacked semiconductor chip in a second direction parallel to the surface of the package substrate.

10. The semiconductor package of claim 9, further comprising a molding film on the base semiconductor chip and the at least one stacked semiconductor chip,
wherein the molding film fills a space between the organic layer and the base semiconductor chip and a space between the organic layer and the at least one stacked semiconductor chip in the second direction parallel to the surface of the package substrate.

11. The semiconductor package of claim 1, further comprising:
a base bonding layer between the package substrate and the base semiconductor chip; and
a connection bonding layer between the base semiconductor chip and the at least one stacked semiconductor chip, and
wherein the base bonding layer and the connection bonding layer each comprise an adhesive resin and a conductive particle dispersed in the adhesive resin.

12. The semiconductor package of claim 11, wherein the at least one stacked semiconductor chip comprises a plurality of stacked semiconductor chips,
wherein the semiconductor package further comprises at least one chip bonding layer between the plurality of stacked semiconductor chips, and
wherein the chip pad is in the at least one chip bonding layer.

13. The semiconductor package of claim 1, wherein the at least one stacked semiconductor chip comprises:
a first stacked semiconductor chip above the base semiconductor chip; and
a second stacked semiconductor chip above the first stacked semiconductor chip,
wherein the at least one connections structure comprises:
a first connection structure in a first portion of the organic layer and connected to the chip pad of the first stacked semiconductor chip; and
a second connection structure in a second portion of the organic layer and connected to the chip pad of the second stacked semiconductor chip,
wherein the first portion of the organic layer is between the first stacked semiconductor chip and the package substrate, and the second portion of the organic layer is between the second stacked semiconductor chip and the package substrate, and
wherein a thickness of the first portion in the first direction and a thickness of the second portion in the first direction are different from each other.

14. The semiconductor package of claim 13, wherein an upper surface of the first portion in the first direction and an upper surface of the base semiconductor chip in the first direction are coplanar with respect to each other.

15. The semiconductor package of claim 13, wherein the first connection structure and the second connection structure extend parallel to each other, and are spaced apart from each other in a second direction parallel to the surface of the package substrate.

16. The semiconductor package of claim 1, wherein, as a distance from the package substrate in the first direction perpendicular to the surface of the package substrate increases, a width of the at least one connection structure gradually decreases in a second direction parallel to the surface of the package substrate.

17. A method of fabricating a semiconductor package, the method comprising:
forming a step-structured organic layer by exposing an organic layer precursor above a base layer;
disposing a base semiconductor chip, comprising a base pad, above the base layer;
disposing a stacked semiconductor chip, comprising a chip pad, above the base semiconductor chip;
forming a trench by etching the step-structured organic layer along a first direction perpendicular to a surface of the base layer;
forming a seed metal layer on a surface of the trench; and
forming a connection structure in the trench by forming a connection layer on the seed metal layer.

18. The method of claim 17, wherein the exposing the organic layer precursor comprises exposing the organic layer precursor using at least one from among phase shift mask (PSM) and nano-imprinting lithography (NIL).

19. The method of claim 17, wherein the disposing the base semiconductor chip comprises contacting the base pad with the base layer, and
wherein the disposing the stacked semiconductor chip comprises contacting the chip pad with the step-structured organic layer.

20. A semiconductor package comprising:
a package substrate;
a base semiconductor chip above the package substrate, and the base semiconductor chip comprising a base pad in contact with the package substrate;
a plurality of stacked semiconductor chips comprising:
a first stacked semiconductor chip that is above the base semiconductor chip and comprises a first chip pad connected to the package substrate; and
a second stacked semiconductor chip that is above the first stacked semiconductor chip and comprising a second chip pad connected to the package substrate;
an organic layer between the package substrate and the plurality of stacked semiconductor chips in a first direction perpendicular to a surface of the package substrate;
a first connection structure extending in the first direction in a first portion of the organic layer, the first connection structure connecting the package substrate and the first chip pad;
a second connection structure extending in the first direction in a second portion of the organic layer, the second connection structure connecting the package substrate and the second chip pad; and
a molding film on the base semiconductor chip and the plurality of stacked semiconductor chips,
wherein the first portion of the organic layer is between the first stacked semiconductor chip and the package substrate, and the second portion of the organic layer is between the second stacked semiconductor chip and the package substrate, and
wherein, in the first direction perpendicular to the surface of the package substrate, a thickness of the first portion and a thickness of the second portion are different from each other.
